(19) United States
(12) Patent Application Publication
(10) Pub. No.: US 2025/0268036 A1
(43) Pub. Date: Aug. 21, 2025

(54) DISPLAY DEVICE

(71) Applicant: Samsung Display Co., Ltd., Yongin-Si (KR)

(72) Inventors: DONG HEE SHIN, Yongin-si (KR); SUNKWUN SON, Yongin-si (KR); SANG YONG NO, Yongin-si (KR)

(21) Appl. No.: 18/973,111

(22) Filed: Dec. 9, 2024

(30) Foreign Application Priority Data
Feb. 16, 2024 (KR) 10-2024-0022396

(51) Int. Cl. H10K 59/131; H10K 59/126

(52) U.S. Cl. CPC H10K 59/131; H10K 59/126

(57) ABSTRACT

A display device includes a base layer, a circuit layer on the base layer, and an element layer on the circuit layer and including light emitting elements and light receiving elements. The circuit layer includes pixel driving circuits connected to the light emitting elements, sensor driving circuits connected to the light receiving elements, gate wirings connected to the pixel driving circuits, first readout lines connected to a first group of sensor driving circuits among the sensor driving circuits, second readout lines connected to a second group of sensor driving circuits among the sensor driving circuits, connecting lines electrically connected with the second readout lines, respectively, in the display area, and a shielding pattern between the gate wirings and the connecting lines.

### CROSS-REFERENCE TO RELATED APPLICATIONS

This application claims priority under 35 U.S.C. § 119 to Korean Patent Application No. 10-2024-0022396 filed on Feb. 16, 2024, in the Korean Intellectual Property Office, the disclosure of which is incorporated by reference herein in its entireties.

### BACKGROUND

Embodiments described herein relate to a display device in which the size of a non-display area is reduced.

A display device may provide functions that enable a user to interact with the display device. For example, a display device may display an image to provide information to the user and may sense a user input such as a user's touch or biometric information. To sense or recognize biometric information, a display device may use a capacitive sensing technique for sensing a change in capacitance between electrodes in the display device, a light sensing technique for sensing incident light using an optical sensor, or an ultrasonic sensing technique for sensing vibration using a piezoelectric element.

### SUMMARY

Embodiments of the present disclosure provide a display device that has a biometric information recognition function and in which the area of a non-display area is relatively small, e.g., reduced when compared to some prior display devices.

According to an embodiment, a display device having a display area and a non-display area includes a base layer, a circuit layer on the base layer, and an element layer that is on the circuit layer and that includes light emitting elements and light receiving elements in the display area.

The circuit layer includes pixel driving circuits connected to the light emitting elements, sensor driving circuits connected to the light receiving elements, data lines connected to the pixel driving circuits, gate wirings connected to the pixel driving circuits, first readout lines connected to a first group of sensor driving circuits among the sensor driving circuits, second readout lines spaced apart from the first readout lines in a first direction and connected to a second group of sensor driving circuits among the sensor driving circuits, connecting lines electrically connected with the second readout lines, respectively, in the display area, and a shielding pattern that overlaps the gate wirings and the connecting lines when viewed from above a plane and that is disposed between the gate wirings and the connecting lines in a normal direction perpendicular to the plane.

According to an embodiment, an electronic device having a display area and a non-display area includes a base layer, a circuit layer on the base layer, and an element layer that is on the circuit layer and that includes light emitting elements and light receiving elements disposed to correspond to the display area.

The circuit layer includes pixel driving circuits connected to the light emitting elements, sensor driving circuits connected to the light receiving elements, data lines connected to the pixel driving circuits, gate wirings connected to the pixel driving circuits, voltage lines connected to the pixel driving circuits, first readout lines connected to a first group of sensor driving circuits among the sensor driving circuits, second readout lines spaced apart from the first readout lines in a first direction and connected to a second group of sensor driving circuits among the sensor driving circuits, vertical connecting lines that are electrically connected with the second readout lines, respectively, in the display area and that cross the gate wirings, and a shielding pattern that overlaps the gate wirings and the vertical connecting lines. The shielding pattern extends from at least one of the voltage lines and is between the gate wirings and the vertical connecting lines in a normal direction perpendicular to the plane.

### BRIEF DESCRIPTION OF THE FIGURES

The above and other objects and features of the present disclosure will become apparent by describing in detail embodiments thereof with reference to the accompanying drawings.

FIG. 1 is a perspective view of a display device according to an embodiment of the present disclosure.

FIG. 2A is an exploded perspective view of the display device according to an embodiment of the present disclosure.

FIG. 2B is a sectional view of the display device according to an embodiment of the present disclosure.

FIG. 3 is a block diagram of the display device according to an embodiment of the present disclosure.

FIG. 4A is a circuit diagram illustrating a pixel and a sensor according to an embodiment of the present disclosure.

FIG. 4B is a waveform diagram illustrating operations of the pixel and the sensor illustrated in FIG. 4A.

FIG. 5A is a plan view of a display panel according to an embodiment of the present disclosure.

FIG. 5B is an enlarged view of a portion of the display panel illustrated in FIG. 5A.

FIG. 6 is a sectional view of a display panel according to an embodiment of the present disclosure.

FIG. 7A is a plan view illustrating a portion of a display panel according to an embodiment of the present disclosure.

FIG. 7B is an enlarged view of portion BB of the display panel illustrated in FIG. 7A.

FIG. 7C is a sectional view taken along line I-I′ illustrated in FIG. 7B.

FIG. 8A is a plan view illustrating a portion of a display panel according to an embodiment of the present disclosure.

FIG. 8B is an enlarged view of portion CC of the display panel illustrated in FIG. 8A.

FIG. 8C is a sectional view taken along line II-II′ illustrated in FIG. 8B.

FIGS. 9A. 9B, 9C, 9D, 9E, 9F, 9G, and 9H are plan views illustrating an arrangement of patterned circuit layers in a display panel according to an embodiment of the present disclosure.

FIG. 10A is a plan view illustrating a portion of a display panel according to an embodiment of the present disclosure.

FIG. 10B is an enlarged view of portion EE of the display panel illustrated in FIG. 10A.

FIG. 11A is a plan view illustrating a portion of a display panel according to an embodiment of the present disclosure.

FIG. 11B is an enlarged view of portion FF of the display panel illustrated in FIG. 11A.

FIGS. 12A and 12B are sectional views illustrating light emitting elements and light receiving elements in a display panel according to an embodiment of the present disclosure.

### DETAILED DESCRIPTION

In this specification, a component (or, an area, a layer, a part, etc.) referred to as being “on”, “connected to” or “coupled to” another component means that the component may be directly on, connected to, or coupled to the other component or a third component may be present therebetween.

Identical reference numerals in different drawings refer to similar or identical components. Additionally, in the drawings, the thicknesses, proportions, and dimensions of components may be exaggerated for ease of illustration or description.

Terms such as first, second, and the like may be used to describe various components, but the components should not be limited by these terms. The terms may be used only for distinguishing one component from other components. For example, without departing the scope of the present disclosure, a first component may instead be referred to as a second component, and similarly, the second component may instead be referred to as the first component. The terms of a singular form may include plural forms unless otherwise specified. As used herein, the term “and/or” includes all combinations of one or more of the related components.

Terms such as “below”, “under”, “above”, and “over” are used herein to describe a relationship of components illustrated in the drawings. The terms are relative concepts and may be described based on directions illustrated in the drawing.

Terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings corresponding to the contextual meanings in the relevant field of art, and terms used herein are not to be interpreted as having ideal or excessively formal meanings unless clearly defined as having such in the present disclosure.

Hereinafter, embodiments of the present disclosure will be described with reference to the accompanying drawings.

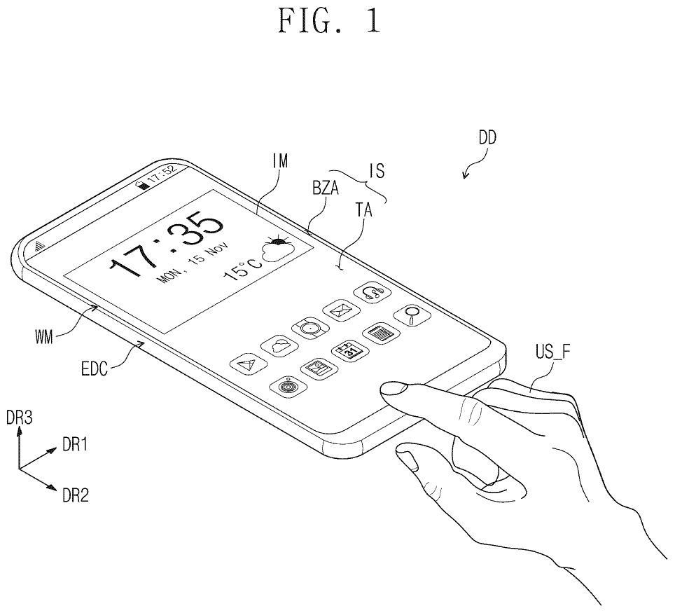

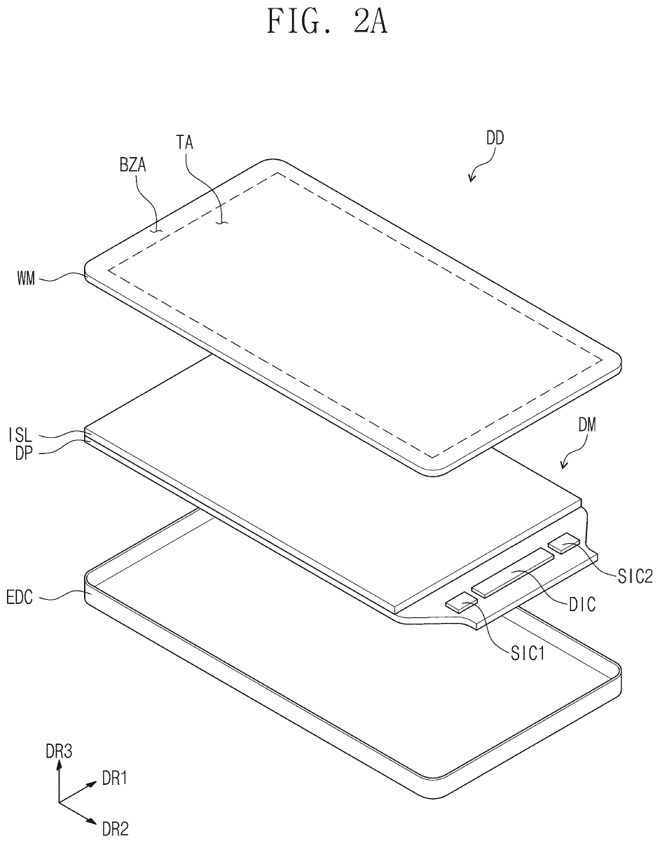

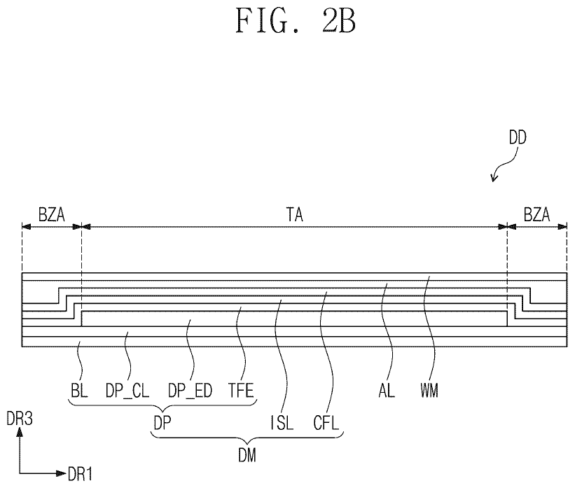

FIG. 1 is a perspective view of a display device according to an embodiment of the present disclosure. FIG. 2A is an exploded perspective view of the display device according to an embodiment of FIG. 1. FIG. 2B is a sectional view of the display device according to an embodiment of FIG. 1.

Referring to FIGS. 1, 2A, and 2B, a display device DD according to an embodiment of the present disclosure may have a rectangular shape with short sides parallel to a first direction DR1 and long sides parallel to a second direction DR2 crossing the first direction DR1. However, without being limited thereto, the display device DD may have various shapes such as a circular shape, a polygonal shape, and the like.

The display device DD may be a device activated electrically. The display device DD may include various embodiments and may be used in various applications. For example, the display device DD may be applied to or in an electronic device such as a smart watch, a tablet computer, a notebook computer, a computer, a smart television, and the like. The display device DD may be referred to as the electronic device.

A third direction DR3 is a normal direction substantially perpendicular to a plane defined by the first direction DR1 and the second direction DR2. The expression “when viewed from above the plane” used herein may mean when viewed with a line of sight along the third direction DR3.

The upper surface of the display device DD may be defined as a display surface IS and may be parallel to the plane defined by the first direction DR1 and the second direction DR2. Images IM generated by the display device DD may be provided to a user through the display surface IS.

The display surface IS may be divided into a transmissive area TA and a bezel area BZA. The transmissive area TA may be an area on which the images IM are displayed. The user may visually recognize the images IM through the transmissive area TA. In this embodiment, the transmissive area TA is illustrated in a rounded quadrangular shape. However, this is illustrative, and the transmissive area TA may have various shapes and is not limited to the illustrated embodiments.

The bezel area BZA is adjacent to the transmissive area TA. The bezel area BZA may have a fixed color, e.g., black. The bezel area BZA may surround the transmissive area TA. Accordingly, the bezel area BZA may define the shape or boundaries of the transmissive area TA. However, this example is illustrative, and the bezel area BZA may be adjacent to only one side of the transmissive area TA or may be omitted.

The display device DD may sense an external input applied to the display device DD from outside the display device DD. The external input may be of various types. For example, the external input may be a part of the user's body (e.g., a hand US_F of the user) or a separate device (e.g., an active pen or a digitizer) contacting the display device DD. The external input is not limited to contact but may correspond to other actions (e.g., hovering) that is applied in proximity to the display device DD or applied adjacent to the display device DD at a certain distance. In addition, the external input may have various forms such as force, pressure, temperature, light, and the like.

The display device DD may sense a user's biometric information. A biometric information sensing area capable of sensing the user's biometric information may be provided on the display surface IS of the display device DD. The biometric information sensing area may cover all of the transmissive area TA or may only be in a portion of the transmissive area TA. FIG. 1 illustrates an example that uses the entire transmissive area TA as a biometric information sensing area.

The display device DD may include a window WM, a display module DM, and a housing EDC. In this embodiment, the window WM and the housing EDC are coupled to each other to form the exterior of the display device DD.

The front surface of the window WM defines the display surface IS of the display device DD. The window WM may include an optically clear insulating material. For example, the window WM may include glass or plastic. The window WM may have a multi-layer structure or a single-layer structure. For example, the window WM may include a stack of plastic films attached together using an adhesive or may include a glass substrate and a plastic film coupled to each other using an adhesive.

The display module DM may include a display panel DP and an input sensing layer ISL. The display panel DP may display an image that depends on an electrical signal, and the input sensing layer ISL may sense an external input applied from outside the display device DD. The external input may take various forms such as described above.

The display panel DP according to an embodiment of the present disclosure may be an emissive display panel, but embodiments are not limited thereto. In some embodiments, the display panel DP may be an organic light emitting display panel, an inorganic light emitting display panel, or a quantum-dot light emitting display panel. An emissive layer of an organic light emitting display panel may include an organic luminescent material, and an emissive layer of an inorganic light emitting display panel may include an inorganic luminescent material. An emissive layer of a quantum-dot light emitting display panel may include quantum dots and quantum rods. Hereinafter, an embodiment in which the display panel DP is an organic light emitting display panel is described as an example.

Referring to FIG. 2B, the display panel DP may include a base layer BL, a circuit layer DP_CL, an element layer DP_ED, and an encapsulation layer TFE. The display panel DP may be a flexible display panel. However, the present disclosure is not limited thereto. For example, the display panel DP may be a foldable display panel that is folded about a folding axis, or the display panel DP may be a rigid display panel.

The base layer BL may include a synthetic resin layer. The synthetic resin layer may be a polyimide-based resin layer, and the material thereof is not particularly limited. In addition, the base layer BL may include a glass substrate, a metal substrate, or an organic/inorganic composite substrate.

The circuit layer DP_CL is on the base layer BL and is between the base layer BL and the element layer DP_ED. The circuit layer DP_CL may include at least one insulating layer and a circuit element. Hereinafter, the insulating layer included in the circuit layer DP_CL is referred to as an intermediate insulating layer. The intermediate insulating layer may include at least one intermediate inorganic film and at least one intermediate organic film. The circuit element may include a plurality of pixel driving circuits, one for each of a plurality of pixels used for displaying an image and a plurality of sensor driving circuits, one for each of a plurality of sensors used for recognizing external information. The external information may be biometric information. In an embodiment of the present disclosure, the sensor may be a fingerprint recognition sensor, a proximity sensor, an iris recognition sensor, a blood pressure measurement sensor, an illuminance sensor, or the like. Alternatively, the sensor may be an optical sensor for optically recognizing biometric information. The circuit layer DP_CL may further include signal lines connected to the pixel driving circuits and/or the sensor driving circuits.

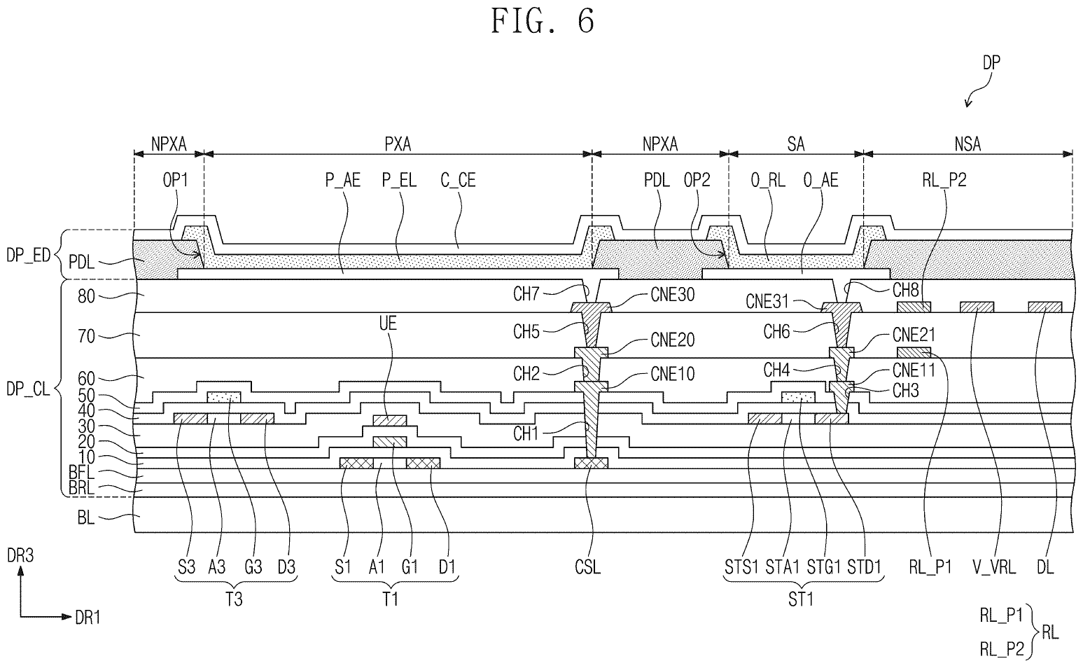

The element layer DP_ED may include light emitting elements in the pixels and light receiving elements in the sensors. In an embodiment of the present disclosure, each light receiving element may be or include a photo diode. In one example, the light receiving element may be a sensor that senses, or reacts to, light reflected by a fingerprint of the user. Embodiments of the circuit layer DP_CL and the element layer DP_ED are described further below with reference to FIGS. 6 to 12B.

The encapsulation layer TFE seals and protects the element layer DP_ED. The encapsulation layer TFE may include at least one organic film and at least one inorganic film. The inorganic film may include an inorganic material and may protect the element layer DP_ED from moisture/oxygen. The inorganic film may include a silicon nitride layer, a silicon oxy nitride layer, a silicon oxide layer, a titanium oxide layer, or an aluminum oxide layer, but is not particularly limited thereto. The organic film may include an organic material and may protect the element layer DP_ED from foreign matter such as dust particles.

The input sensing layer ISL may be formed on the display panel DP. The input sensing layer ISL may be directly on the encapsulation layer TFE. According to an embodiment of the present disclosure, a continuous process may form at least one upper layer of the display panel DP and then the input sensing layer ISL. That is, when the input sensing layer ISL is directly on the display panel DP, an adhesive film is not between the input sensing layer ISL and the encapsulation layer TFE. Alternatively, an adhesive film may be disposed between the input sensing layer ISL and the display panel DP. In this case, the input sensing layer ISL may not be manufactured together with the display panel DP by a continuous process and may be manufactured separately from the display panel DP and then fixed to the upper surface of the display panel DP using the adhesive film.

The input sensing layer ISL may sense an external input (e.g., a touch of the user), may generate a certain input signal that depends on the external input, and may provide the input signal to the display panel DP. The input sensing layer ISL may include a plurality of sensing electrodes for sensing the external input. The sensing electrodes may sense the external input using a capacitive type sensing process. The display panel DP may receive the input signal from the input sensing layer ISL and may generate an image corresponding to the input signal.

The display module DM may further include a color filter layer CFL. In an embodiment of the present disclosure, the color filter layer CFL may be on the input sensing layer ISL. However, the present disclosure is not limited thereto. The color filter layer CFL may be between the display panel DP and the input sensing layer ISL. The color filter layer CFL may include a plurality of color filters and a black matrix.

The structures of the input sensing layer ISL and the color filter layer CFL are described further below.

The display device DD according to an embodiment of the present disclosure may further include an adhesive layer AL. The adhesive layer AL may attach the window WM to the input sensing layer ISL. The adhesive layer AL may include an optically clear adhesive, an optically clear adhesive resin, or a pressure sensitive adhesive (PSA).

The display module DM may further include a driver chip DIC and sensor chips SIC1 and SIC2 as shown in FIG. 2A. In an embodiment of the present disclosure, the driver chip DIC and the sensor chips SIC1 and SIC2 may be mounted on the display panel DP. The driver chip DIC and the sensor chips SIC1 and SIC2 may be adjacent to one end portion (hereinafter, referred to as the first end portion) of the display panel DP. Although FIG. 2A illustrates an example in which the driver chip DIC and the sensor chips SIC1 and SIC2 are adjacent to the first end portion of the display panel DP, the present disclosure is not limited thereto. For example, the driver chip DIC may be disposed adjacent to the first end portion of the display panel DP, and the sensor chips SIC1 and SIC2 may be disposed adjacent to a second end portion of the display panel DP that faces away from the first end portion.

In an embodiment of the present disclosure, the sensor chips SIC1 and SIC2 may include the first sensor chip SIC1 on one side (hereinafter, referred to as the first side) of the driver chip DIC and the second sensor chip SIC2 on a second side of the driver chip DIC that is different from the first side. Alternatively, the first and second sensor chips SIC1 and SIC2 may be integrated into one sensor chip, and the one sensor chip may be adjacent to the driver chip DIC. In the present disclosure, the number of sensor chips SIC1 and SIC2 and the number of driver chips DIC are not particularly limited.

The housing EDC may be coupled to the window WM. The housing EDC with the window WM provide an inner space of the display device DD. The display module DM may be accommodated in the inner space. The housing EDC may include a material having a relatively high rigidity. For example, the housing EDC may include glass, plastic, or metal, or may include a plurality of frames and/or plates formed of a combination thereof. The housing EDC may stably protect components in the inner space of the display device DD from external impact. Although not illustrated, a battery module for supplying power required for overall operation of the display device DD may be disposed between the display module DM and the housing EDC.

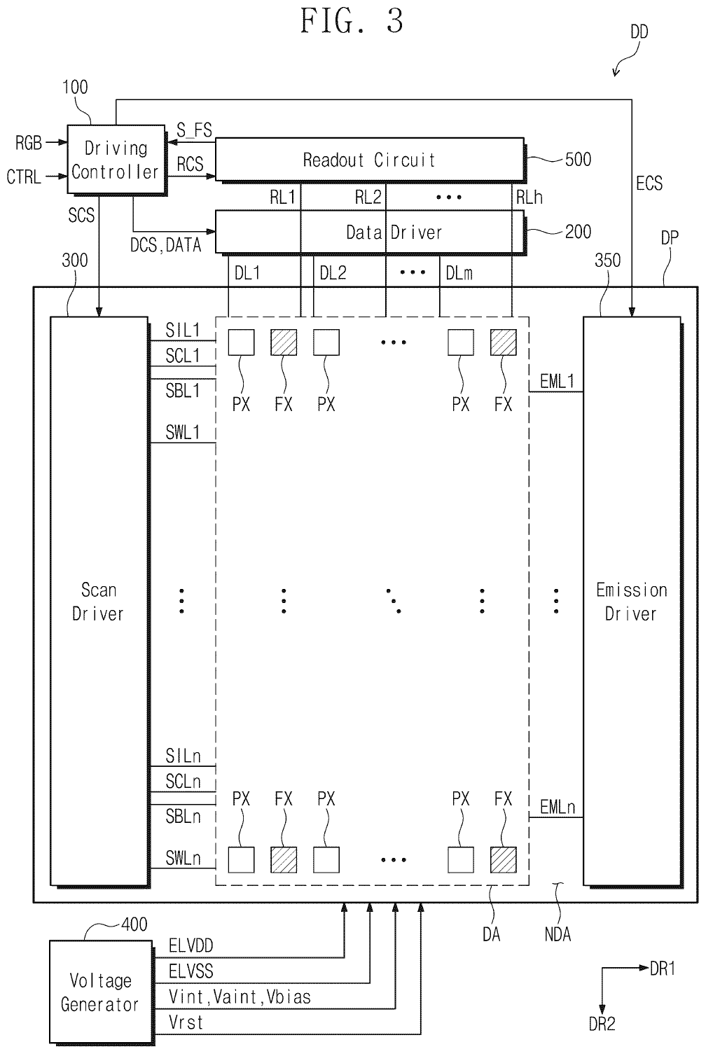

FIG. 3 is a block diagram of the display device according to an embodiment of the present disclosure.

Referring to FIG. 3, the display device DD includes the display panel DP, a panel driver, and a driving controller 100. In an embodiment of the present disclosure, the panel driver includes a data driver 200, a scan driver 300, an emission driver 350, a voltage generator 400, and a readout circuit 500.

The driving controller 100 receives an image signal RGB and a control signal CTRL. The driving controller 100 generates image data DATA by converting the data format of the image signal RGB according to the specification of an interface with the data driver 200. The driving controller 100 outputs a first control signal SCS, a second control signal ECS, a third control signal DCS, and a fourth control signal RCS.

The data driver 200 receives the third control signal DCS and the image data DATA from the driving controller 100. The data driver 200 converts the image data DATA into data signals and outputs the data signals to a plurality of data lines DL1 to DLm that are described further below. The data signals may be analog voltages corresponding to gray level values of the image data DATA. In an embodiment of the present disclosure, the data driver 200 may be embedded in the driver chip DIC illustrated in FIG. 2A.

The scan driver 300 receives the first control signal SCS from the driving controller 100. The scan driver 300 may output scan signals to scan lines in response to the first control signal SCS.

The voltage generator 400 generates voltages required for operation of the display panel DP. In the illustrated embodiment, the voltage generator 400 generates a first driving voltage ELVDD, a second driving voltage ELVSS, a first initialization voltage Vint, a second initialization voltage Vaint, a bias voltage Vbias, and a reset voltage Vrst.

The display panel DP may include a display area DA corresponding to the transmissive area TA (illustrated in FIG. 1) and a non-display area NDA corresponding to the bezel area BZA (illustrated in FIG. 1).

The display panel DP may include a plurality of pixels PX disposed in the display area DA and a plurality of sensors FX disposed in the display area DA. In an embodiment of the present disclosure, each of the sensors FX may be disposed between two pixels PX that are adjacent to each other. The pixels PX and the sensors FX may be arranged to alternate along the first and second directions DR1 and DR2. However, the present disclosure is not limited thereto. That is, two or more pixels PX may be disposed between two sensors FX that are adjacent to each other in the first direction DR1 among the plurality of sensors FX, or two or more pixels PX may be disposed between two sensors FX that are adjacent to each other in the second direction DR2 among the plurality of sensors FX.

The display panel DP further includes initialization scan lines SIL1 to SILn, compensation scan lines SCL1 to SCLn, write scan lines SWL1 to SWLn, black scan lines SBL1 to SBLn, emission control lines EML1 to EMLn, the data lines DL1 to DLm, and readout lines RL1 to RLh. The initialization scan lines SIL1 to SILn, the compensation scan lines SCL1 to SCLn, the write scan lines SWL1 to SWLn, the black scan lines SBL1 to SBLn, and the emission control lines EML1 to EMLn extend in the first direction DR1. The initialization scan lines SIL1 to SILn, the compensation scan lines SCL1 to SCLn, the write scan lines SWL1 to SWLn, the black scan lines SBL1 to SBLn, and the emission control lines EML1 to EMLn are arranged in the second direction DR2 so as to be spaced apart from one another. The data lines DL1 to DLm and the readout lines RL1 to RLh extend in the second direction DR2 and are arranged in the first direction DR1 so as to be spaced apart from one another. Here, “n”, “m”, and “h” are natural numbers that are 1 or more.

The plurality of pixels PX are electrically connected to the initialization scan lines SIL1 to SILn, the compensation scan lines SCL1 to SCLn, the write scan lines SWL1 to SWLn, the black scan lines SBL1 to SBLn, the emission control lines EML1 to EMLn, and the data lines DL1 to DLm. For example, each of the plurality of pixels PX may be electrically connected to four scan lines. However, without being limited thereto, the number of scan lines connected to each pixel PX may be changed.

The plurality of sensors FX are electrically connected to the write scan lines SWL1 to SWLn and the readout lines RL1 to RLh. Each of the plurality of sensors FX may be electrically connected to one scan line. However, the present disclosure is not limited thereto. The number of scan lines connected to each sensor FX may be varied. In an embodiment of the present disclosure, the number of readout lines RL1 to RLh may be smaller than or equal to the number of data lines DL1 to DLm. For example, the number of readout lines RL1 to RLh may correspond to ½, ¼, or ⅛ of the number of data lines DL1 to DLm.

The scan driver 300 may be disposed in the non-display area NDA of the display panel DP. The scan driver 300 receives the first control signal SCS from the driving controller 100. In response to the first control signal SCS, the scan driver 300 may output initialization scan signals to the initialization scan lines SIL1 to SILn and may output compensation scan signals to the compensation scan lines SCL1 to SCLn. Furthermore, in response to the first control signal SCS, the scan driver 300 may output write scan signals to the write scan lines SWL1 to SWLn and may output black scan signals to the black scan lines SBL1 to SBLn. Alternatively, the scan driver 300 may include first and second scan drivers. The first scan driver may output the initialization scan signals and the compensation scan signals, and the second scan driver may output the write scan signals and the black scan signals.

The emission driver 350 may be disposed in the non-display area NDA of the display panel DP. The emission driver 350 receives the second control signal ECS from the driving controller 100. In response to the second control signal ECS, the emission driver 350 may output emission control signals to the emission control lines EML1 to EMLn. Alternatively, the scan driver 300 may be connected to the emission control lines EML1 to EMLn. In this case, the emission driver 350 may be omitted, and the scan driver 300 may output the emission control signals to the emission control lines EML1 to EMLn.

The readout circuit 500 receives the fourth control signal RCS from the driving controller 100. In response to the fourth control signal RCS, the readout circuit 500 may receive or process detection signals from the readout lines RL1 to RLh. The readout circuit 500 may process the detection signals received from the readout lines RL1 to RLh and may provide the processed detection signals S_FS to the driving controller 100. The driving controller 100 may recognize biometric information based on the detection signals S_FS. In an embodiment of the present disclosure, the readout circuit 500 may be embedded in the sensor chips SIC1 and SIC2 illustrated in FIG. 2A.

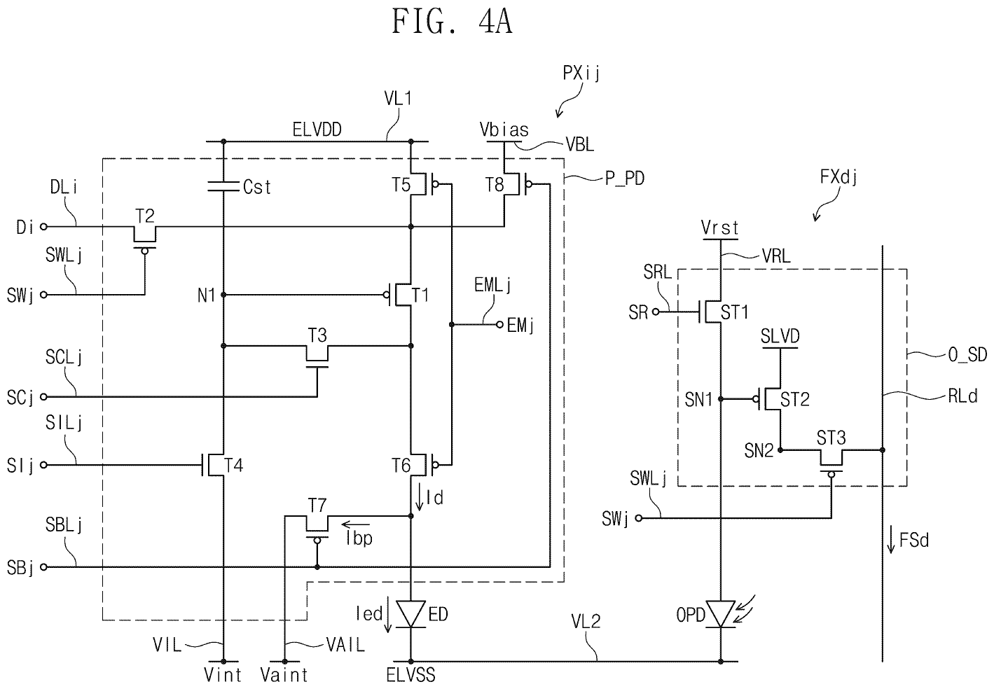

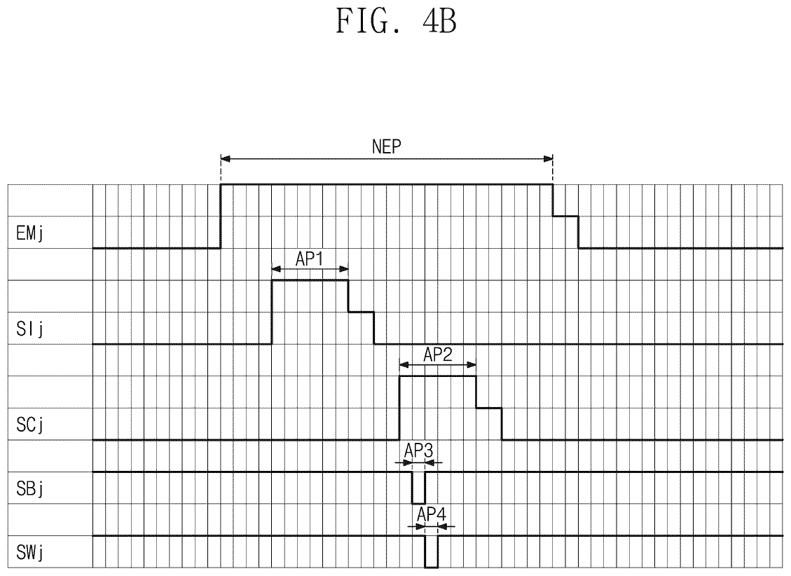

FIG. 4A is a circuit diagram illustrating a pixel and a sensor according to an embodiment of the present disclosure, and FIG. 4B is a waveform diagram showing emission and scan signals during operations of the pixel and the sensor illustrated in FIG. 4A.

FIG. 4A shows an equivalent circuit diagram of one pixel PXij among the plurality of pixels PX illustrated in FIG. 3. Each of the pixels PX may have the same circuit structure, so that description of the circuit structure of the pixel PXij may apply all pixels PX, and detailed description of the other pixels will be omitted. FIG. 4A further shows an equivalent circuit diagram of one sensor FXdj among the plurality of sensors FX illustrated in FIG. 3. Each of the sensors FX may have the same circuit structure, so that description of the circuit structure of the sensor FXdj may apply to all sensors FX, and detailed description of the other sensors will be omitted.

Referring to FIG. 4A, the pixel PXij is connected to the i-th data line DLi among the data lines DL1 to DLm, the j-th initialization scan line SILj among the initialization scan lines SIL1 to SILn, the j-th compensation scan line SCLj among the compensation scan lines SCL1 to SCLn, the j-th write scan line SWLj among the write scan lines SWL1 to SWLn, the j-th black scan line SBLj among the black scan lines SBL1 to SBLn, and the j-th emission control line EMLj among the emission control lines EML1 to EMLn.

The pixel PXij includes a light emitting element ED and a pixel driving circuit P_PD. The light emitting element ED may be a light emitting diode. In an embodiment of the present disclosure, the light emitting element ED may be an organic light emitting diode including an organic light emitting layer.

The pixel driving circuit P_PD includes first to eighth transistors T1, T2, T3, T4, T5, T6, T7, and T8 and one capacitor Cst. At least one of the first to eighth transistors T1 to T8 may be a transistor having a low-temperature polycrystalline silicon (LTPS) semiconductor layer. Some of the first to eighth transistors T1 to T8 may be P-type transistors, and the others may be N-type transistors. At least one of the first to eighth transistors T1 to T8 may be a transistor having an oxide semiconductor layer. For example, the third and fourth transistors T3 and T4 may be oxide semiconductor transistors, and the first, second, and fifth to eighth transistors T1, T2, and T5 to T8 may be LTPS transistors. The third and fourth transistors T3 and T4 may be NMOS transistors.

The configuration of the pixel driving circuit P_PD according to the present disclosure is not limited to the embodiment illustrated in FIG. 4A. The pixel driving circuit P_PD illustrated in FIG. 4A is merely an example, and various changes and modifications may be made to the configuration of the pixel driving circuit P_PD. For example, the first, second, and fifth to eighth transistors T1, T2, and T5 to T8 may all be P-type transistors or N-type transistors.

The j-th initialization scan line SILj, the j-th compensation scan line SCLj, the j-th write scan line SWLj, the j-th black scan line SBLj, and the j-th emission control line EMLj may transfer the j-th initialization scan signal SIj, the j-th compensation scan signal SCj, the j-th write scan signal SWj, the j-th black scan signal SBj, and the j-th emission control signal EMj, respectively, to the pixel PXij. The i-th data line DLi transfers the i-th data signal Di to the pixel PXij. The i-th data signal Di may have a voltage level corresponding to the image signal RGB (refer to FIG. 3) that is input to the display device DD (refer to FIG. 3).

In an embodiment of the present disclosure, the pixel PXij may be connected to first and second driving voltage lines VL1 and VL2, first and second initialization voltage lines VIL and VAIL, and a bias voltage line VBL. The first driving voltage line VL1 may transfer the first driving voltage ELVDD to the pixel PXij, and the second driving voltage line VL2 may transfer the second driving voltage ELVSS to the pixel PXij. In addition, the first initialization voltage line VIL may transfer the first initialization voltage Vint to the pixel PXij, and the second initialization voltage line VAIL may transfer the second initialization voltage Vaint to the pixel PXij. The bias voltage line VBL may transfer the bias voltage Vbias to the pixel PXij.

The first transistor T1 is connected between the first driving voltage line VL1, which receives the first driving voltage ELVDD, and the light emitting element ED. The first transistor T1 includes a first electrode connected with the first driving voltage line VL1 via the fifth transistor T5, a second electrode connected with an anode electrode of the light emitting element ED via the sixth transistor T6, and a third electrode (e.g., a gate electrode) connected with one end of the capacitor Cst (e.g., a first node N1). The first transistor T1 may receive the i-th data signal Di that the i-th data line DLi transfers depending on a switching operation of the second transistor T2 and may supply a driving current Id to an anode electrode of the light emitting element ED.

The second transistor T2 is connected between the i-th data line DLi and the first electrode of the first transistor T1. The second transistor T2 includes a first electrode connected with the i-th data line DLi, a second electrode connected with the first electrode of the first transistor T1, and a third electrode (e.g., a gate electrode) connected with the j-th write scan line SWLj. The second transistor T2 may be turned on or off depending on the j-th write scan signal SWj transferred through the j-th write scan line SWLj and may transfer, to the first electrode of the first transistor T1, the i-th data signal Di from the i-th data line DLi.

The third transistor T3 is connected between the second electrode of the first transistor T1 and the first node N1. The third transistor T3 includes a first electrode connected with the third electrode of the first transistor T1, a second electrode connected with the second electrode of the first transistor T1, and a third electrode (e.g., a gate electrode) connected with the j-th compensation scan line SCLj. The third transistor T3 may be turned on or off depending on the j-th compensation scan signal SCj transferred through the j-th compensation scan line SCLj and may connect the first transistor T1 in the form of a diode by connecting the third electrode and the second electrode of the first transistor T1.

The fourth transistor T4 is connected between the first initialization voltage line VIL to which the first initialization voltage Vint is applied and the first node N1. The fourth transistor T4 includes a first electrode connected with the first initialization voltage line VIL through which the first initialization voltage Vint is transferred, a second electrode connected with the first node N1, and a third electrode (e.g., a gate electrode) connected with the j-th initialization scan line SILj. The fourth transistor T4 is turned on or off depending on the j-th initialization scan signal SIj transferred through the j-th initialization scan line SILj. The turned-on fourth transistor T4 initializes the potential of the third electrode of the first transistor T1 (that is, the potential of the first node N1) by transferring the first initialization voltage Vint to the first node N1.

The fifth transistor T5 includes a first electrode connected with the first driving voltage line VL1, a second electrode connected with the first electrode of the first transistor T1, and a third electrode (e.g., a gate electrode) connected to the j-th emission control line EMLj.

The sixth transistor T6 includes a first electrode connected with the second electrode of the first transistor T1, a second electrode connected to the anode electrode of the light emitting element ED, and a third electrode (e.g., a gate electrode) connected to the j-th emission control line EMLj.

The fifth and sixth transistors T5 and T6 are simultaneously turned on or off depending on the j-th emission control signal EMj transferred through the j-th emission control line EMLj. The first driving voltage ELVDD applied through the turned-on fifth transistor T5 may be compensated for through the first transistor T1 connected in the form of a diode and thereafter may be transferred to the light emitting element ED.

The seventh transistor T7 includes a first electrode connected to the second initialization voltage line VAIL through which the second initialization voltage Vaint is transferred, a second electrode connected with the second electrode of the sixth transistor T6, and a third electrode (e.g., a gate electrode) connected with the j-th black scan line SBLj. The second initialization voltage Vaint may have a voltage level lower than or equal to the voltage level of the first initialization voltage Vint.

The eighth transistor T8 includes a first electrode connected to the bias voltage line VBL through which the bias voltage Vbias is transferred, a second electrode connected with the first electrode of the first transistor T1, and a third electrode (e.g., a gate electrode) connected with the j-th black scan line SBLj.

The seventh and eighth transistors T7 and T8 are simultaneously turned on or off depending on the j-th black scan signal SBj transferred through the j-th black scan line SBLj. The second initialization voltage Vaint applied through the turned-on seventh transistor T7 may be transferred to the anode electrode of the light emitting element ED. Accordingly, the anode electrode of the light emitting element ED may be initialized to the second initialization voltage Vaint. The bias voltage Vbias applied through the turned-on eighth transistor T8 may be transferred to the first electrode of the first transistor T1. Accordingly, the bias voltage Vbias may be periodically applied to the first electrode of the first transistor T1. As a result, deterioration in display quality due to an increase in the potential difference between the first and second electrodes of the first transistor T1 to a certain level or higher by a magnetic hysteresis phenomenon may be prevented.

The one end of the capacitor Cst is connected with the third electrode of the first transistor T1 as described above, and the opposite end of the capacitor Cst is connected with the first driving voltage line VL1. A cathode electrode of the light emitting element ED may be connected with the second driving voltage line VL2 that transfers the second driving voltage ELVSS. The second driving voltage ELVSS may have a lower voltage level than the first driving voltage ELVDD. In an embodiment of the present disclosure, the second driving voltage ELVSS may have a lower voltage level than the first and second initialization voltages Vint and Vaint.

Referring to FIGS. 4A and 4B, the j-th emission control signal EMj has a high level during a non-light emission period NEP. Within the non-light emission period NEP, the j-th initialization scan signal SIj is activated, e.g., to a high level. When the j-th initialization scan signal SIj having the high level is provided through the j-th initialization scan line SILj during an activation period AP1 (hereinafter, referred to as a first activation period) of the j-th initialization scan signal SIj, the fourth transistor T4 turns on in response to the j-th initialization scan signal SIj having the high level. The first initialization voltage Vint is transferred to the third electrode of the first transistor T1 through the turned-on fourth transistor T4, and the first node N1 is initialized to the first initialization voltage Vint. Accordingly, the first activation period AP1 may be defined as an initialization period of the pixel PXij.

Next, when the j-th compensation scan signal SCj is activated and the j-th compensation scan signal SCj having a high level is supplied through the j-th compensation scan line SCLj during an activation period AP2 (hereinafter, referred to as a second activation period) of the j-th compensation scan signal SCj, the third transistor T3 is turned on. The third transistor T3 when turned on connects the first transistor T1 in the form of a diode that is forward-biased. The first activation period AP1 may not overlap the second activation period AP2.

Within the second activation period AP2, the j-th write scan signal SWj is activated. The j-th write scan signal SWj has a low level during an activation period AP4 (hereinafter, referred to as a fourth activation period). During the fourth activation period AP4, the second transistor T2 is turned on by the j-th write scan signal SWj having the low level. Then, a compensation voltage “Di-Vth” obtained by subtracting the threshold voltage Vth of the first transistor T1 from the i-th data signal Di supplied from the i-th data line DLi is applied to the third electrode of the first transistor T1. That is, the potential of the third electrode of the first transistor T1 may be the compensation voltage “Di-Vth”. The fourth activation period AP4 may overlap the second activation period AP2. The duration time of the second activation period AP2 may be greater than the duration time of the fourth activation period AP4.

The first driving voltage ELVDD and the compensation voltage “Di-Vth” may be applied to the opposite ends of the capacitor Cst, and charges corresponding to a difference between voltages at the opposite ends of the capacitor Cst may be stored in the capacitor Cst. Here, the period during which the j-th compensation scan signal SCj has the high level may be referred to as a compensation period of the pixel PXij.

Meanwhile, the j-th black scan signal SBj is activated within the second activation period AP2 of the j-th compensation scan signal SCj. The j-th black scan signal SBj has a low level during an activation period AP3 (hereinafter, referred to as a third activation period). During the third activation period AP3, the seventh transistor T7 is turned on by receiving the j-th black scan signal SBj having the low level through the j-th black scan line SBLj. A portion of the driving current Id may escape through the seventh transistor T7 as a bypass current Ibp. The third activation period AP3 may overlap the second activation period AP2. The duration time of the second activation period AP2 may be greater than the duration time of the third activation period AP3. The third activation period AP3 may precede the fourth activation period AP4 and may not overlap the fourth activation period AP4.

When the pixel PXij displays a black image, the pixel PXij is not able to normally display the black image if the light emitting element ED emits light even though the minimum driving current of the first transistor T1 flows as the driving current Id. Accordingly, the seventh transistor T7 in the pixel PXij according to an embodiment of the present disclosure may distribute a portion of the minimum driving current of the first transistor T1 as the bypass current Ibp to a current path other than the current path toward the light emitting element ED. Here, the minimum driving current of the first transistor T1 means a current flowing to the first transistor T1 under the condition that a gate-source voltage Vgs of the first transistor T1 is lower than the threshold voltage Vth so that the first transistor T1 is turned off. The minimum driving current (e.g., a current of about 10 pA or less) flowing to the first transistor T1 under the condition that the first transistor T1 is turned off is transferred to the light emitting element ED, and a black gray-scale image is displayed. When the pixel PXij displays the black image, an influence of the bypass current Ibp on the minimum driving current is relatively great, whereas when the pixel PXij displays an image such as a general image or a white image, the bypass current Ibp has little influence on the driving current Id. Accordingly, when the pixel PXij displays the black image, the current obtained by subtracting the bypass current Ibp escaping through the seventh transistor T7 from the driving current Id (that is, a light emission current led) may be provided to the light emitting element ED so that the pixel PXij may clearly express the black image. Thus, the pixel PXij may implement an accurate black in a gray-scale image using the seventh transistor T7, thereby improving the contrast ratio.

After that, the j-th emission control signal EMj supplied from the j-th emission control line EMLj is changed from the high level to a low level. The fifth and sixth transistors T5 and T6 are turned on by the emission control signal EMj having the low level. Then, the driving current Id depending on the difference between the voltage of the third electrode of the first transistor T1 and the first driving voltage ELVDD is generated. The driving current Id is supplied to the light emitting element ED through the sixth transistor T6, and the light emission current led flows through the light emitting element ED.

Referring again to FIG. 4A, the sensor FXdj is connected to the d-th readout line RLd among the readout lines RL1 to RLh, the j-th write scan line SWLj, and a reset control line SRL.

The sensor FXdj includes a light receiving element OPD and a sensor driving circuit O_SD. In an embodiment of the present disclosure, the light receiving element OPD may be an organic photo diode including an organic material as a photoelectric conversion layer. Although FIG. 4A illustrates the structure in which the sensor FXdj includes one light receiving element, the present disclosure is not limited thereto. For example, the sensor FXdj may include a plurality of light receiving elements OPD connected in parallel.

An anode electrode of the light receiving element OPD may be connected to a first sensing node SN1, and a cathode electrode of the light receiving element OPD may be connected with the second driving voltage line VL2 that transfers the second driving voltage ELVSS. The cathode electrode of the light receiving element OPD may be electrically connected with the cathode electrode of the light emitting element ED. In an embodiment of the present disclosure, the cathode electrode of the light receiving element OPD may be integrally formed with the cathode electrode of the light emitting element ED and may form a common cathode electrode C_CE (refer to FIG. 6).

The sensor driving circuit O_SD includes three transistors ST1, ST2, and ST3. The three transistors ST1, ST2, and ST3 may be the reset transistor ST1, the amplifying transistor ST2, and the output transistor ST3, respectively. At least one of the reset transistor ST1, the amplifying transistor ST2, and the output transistor ST3 may be an oxide semiconductor transistor. In an embodiment of the present disclosure, the reset transistor ST1 may be an oxide semiconductor transistor, and the amplifying transistor ST2 and the output transistor ST3 may be LTPS transistors. However, without being limited thereto, the reset transistor ST1 and the output transistor ST3 may be oxide semiconductor transistors, and the amplifying transistor ST2 may be an LTPS transistor.

Some of the reset transistor ST1, the amplifying transistor ST2, and the output transistor ST3 may be P-type transistors, and the rest may be N-type transistors. In an embodiment of the present disclosure, the amplifying transistor ST2 and the output transistor ST3 may be PMOS transistors, and the reset transistor ST1 may be an NMOS transistor. However, without being limited thereto, the reset transistor ST1, the amplifying transistor ST2, and the output transistor ST3 may all be N-type transistors or P-type transistors.

One or more (e.g., the reset transistor ST1) of the reset transistor ST1, the amplifying transistor ST2, and the output transistor ST3 may be of the same type as the third and fourth transistors T3 and T4 of the pixel PXij. The amplifying transistor ST2 and the output transistor ST3 may be transistors of the same type as the first, second, and fifth to eighth transistors T1, T2, and T5 to T8 of the pixel PXij.

The circuit configuration of the sensor driving circuit O_SD according to the present disclosure is not limited to that illustrated in FIG. 4A. FIG. 4A merely shows an example embodiment of the sensor driving circuit O_SD, and various changes and modifications may be made to the configuration of the sensor driving circuit O_SD.

In the embodiment of FIG. 4A, the reset transistor ST1 includes a first electrode that receives the reset voltage Vrst, a second electrode connected with the first sensing node SN1, and a third electrode (e.g., a gate electrode) that receives a reset control signal SR. The reset transistor ST1 may reset the potential of the first sensing node SN1 to the reset voltage Vrst in response to the reset control signal SR. The reset control signal SR may be a signal provided through the reset control line SRL. However, the present disclosure is not limited thereto. Alternatively, the reset control signal SR may be the j-th compensation scan signal SCj supplied through the j-th compensation scan line SCLj. That is, the reset transistor ST1 may receive the j-th compensation scan signal SCj, which is supplied from the j-th compensation scan line SCLj, as the reset control signal SR. In an embodiment of the present disclosure, the reset voltage Vrst may have a lower voltage level than the second driving voltage ELVSS at least during an activation period of the reset control signal SR. The reset voltage Vrst may be transferred to the sensor FXdj through a reset voltage line VRL. The reset voltage Vrst may be a DC voltage maintained at a voltage level lower than that of the second driving voltage ELVSS.

The reset transistor ST1 may include a plurality of sub-reset transistors connected in series. For example, the reset transistor ST1 may include two sub-reset transistors (hereinafter, referred to as the first and second sub-reset transistors). In this case, a third electrode of the first sub-reset transistor and a third electrode of the second sub-reset transistor are connected to the reset control line SRL. Furthermore, a second electrode of the first sub-reset transistor and a first electrode of the second sub-reset transistor may be electrically connected with each other. In addition, the reset voltage Vrst may be applied to a first electrode of the first sub-reset transistor, and a second electrode of the second sub-reset transistor may be electrically connected with the first sensing node SN1. However, the number of sub-reset transistors is not limited thereto and may be modified in various ways.

The amplifying transistor ST2 includes a first electrode that receives a sensing driving voltage SLVD, a second electrode connected with a second sensing node SN2, and a third electrode (e.g., a gate electrode) connected with the first sensing node SN1. The amplifying transistor ST2 may be turned on depending on the potential of the first sensing node SN1 and may apply the sensing driving voltage SLVD to the second sensing node SN2. In an embodiment of the present disclosure, the sensing driving voltage SLVD may be one of the first driving voltage ELVDD, the first initialization voltage Vint, and the second initialization voltage Vaint. When the sensing driving voltage SLVD is the first driving voltage ELVDD, the first electrode of the amplifying transistor ST2 may be electrically connected to the first driving voltage line VL1. When the sensing driving voltage SLVD is the first initialization voltage Vint, the first electrode of the amplifying transistor ST2 may be electrically connected to the first initialization voltage line VIL, and when the sensing driving voltage SLVD is the second initialization voltage Vaint, the first electrode of the amplifying transistor ST2 may be electrically connected to the second initialization voltage line VAIL.

The output transistor ST3 includes a first electrode connected with the second sensing node SN2, a second electrode connected with the d-th readout line RLd, and a third electrode that receives an output control signal. In response to the output control signal, the output transistor ST3 may transfer a detection signal FSd to the d-th readout line RLd. The output control signal may be the j-th write scan signal SWj supplied through the j-th write scan line SWLj. That is, the output transistor ST3 may receive the j-th write scan signal SWj, which is supplied from the j-th write scan line SWLj, as the output control signal.

The light receiving element OPD of the sensor FXdj may be exposed to light during a light emission period of the light emitting element ED. The light may be light output from the light emitting element ED.

If the user's hand US_F (refer to FIG. 1) touches the display surface IS (refer to FIG. 1), the light receiving element OPD generates photo-charges corresponding to light reflected by ridges of a fingerprint or valleys between the ridges. The amount of current flowing through the light receiving element OPD varies depending on the generated photo-charges. When the light receiving element OPD receives light reflected by the ridges of the fingerprint, a current flowing through the light receiving element OPD may be referred to as a first current, and when the light receiving element OPD receives light reflected by the valleys of the fingerprint, a current flowing through the light receiving element OPD may be referred to as a second current The amount of light reflected by the ridges of the fingerprint and the amount of light reflected by the valleys of the fingerprint are different from each other, and the difference between the amounts of light appears as a difference between the first and second currents. When the first current flows through the light receiving element OPD, the potential of the first sensing node SN1 may be referred to as a first potential, and when the second current flows through the light receiving element OPD, the potential of the first sensing node SN1 may be referred to as a second potential. In an embodiment of the present disclosure, the first current may be greater than the second current. In this case, the first potential may be lower than the second potential.

The amplifying transistor ST2 may be a source follower amplifier that generates a source-drain current in proportion to the potential of the first sensing node SN1 that is input to the third electrode.

During the fourth activation period AP4, the j-th write scan signal SWj having the low level is supplied to the output transistor ST3 through the j-th write scan line SWLj. When the output transistor ST3 is turned on in response to the j-th write scan signal SWj having the low level, the detection signal FSd corresponding to a current flowing through the amplifying transistor ST2 may be output to the d-th readout line RLd.

When the reset control signal SR having a high level is supplied through the reset control line SRL during a reset period, the reset transistor ST1 is turned on. The reset period may be defined as an activation period (that is, a high-level period) of the reset control signal SR. Alternatively, when the reset transistor ST1 is implemented with a P-type transistor, the reset control signal SR having a low level may be supplied to the reset control line SRL during the reset period. The first sensing node SN1 may be reset to a potential corresponding to the reset voltage Vrst during the reset period. In an embodiment of the present disclosure, the reset voltage Vrst may have a lower voltage level than the second driving voltage ELVSS.

When the reset period ends, the light receiving element OPD may generate photo-charges corresponding to received light, and the generated photo-charges may accumulate in the first sensing node SN1.

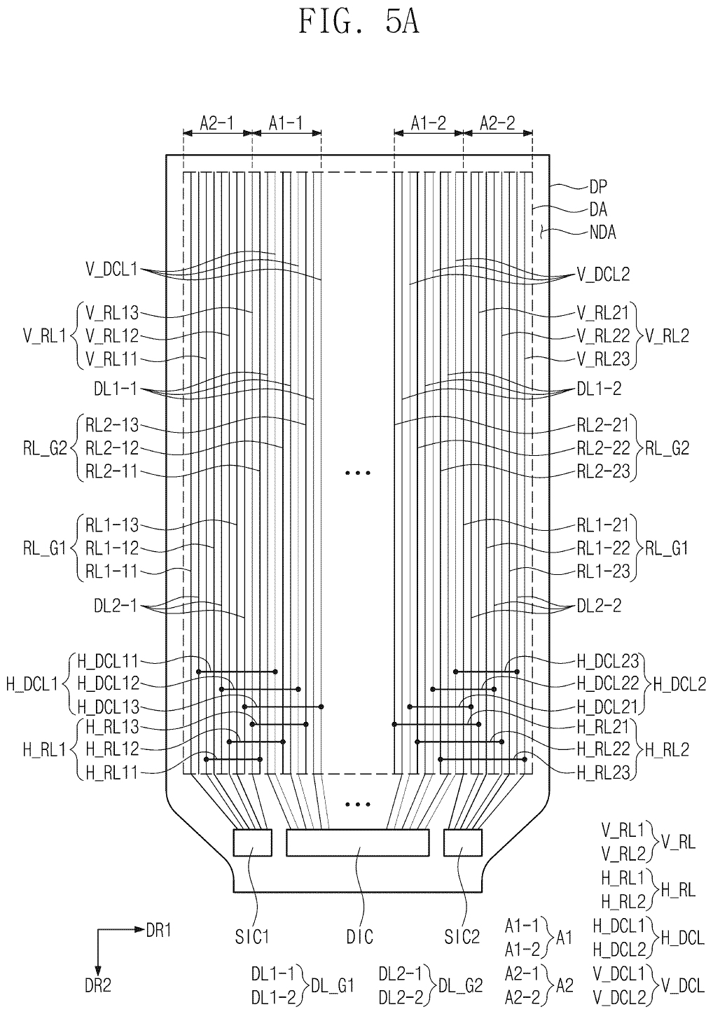

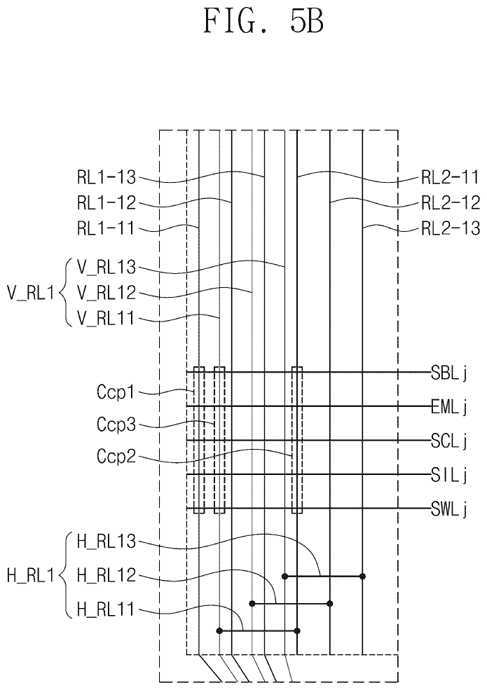

FIG. 5A is a plan view of the display panel according to an embodiment of the present disclosure. FIG. 5B is an enlarged view of a portion of the display panel illustrated in FIG. 5A. For convenience of description and illustration clarity, FIG. 5A only shows the data lines and the readout lines and does not show the scan lines and the emission control lines.

Referring to FIG. 5A, the display panel DP includes the display area DA and the non-display area NDA. The plurality of pixels PX (refer to FIG. 3) and the plurality of sensors FX (refer to FIG. 3) are in the display area DA. The driver chip DIC and the sensor chips SIC1 and SIC2 are mounted on the non-display area NDA.

The data lines DL1 to DLm (refer to FIG. 3) are connected to the plurality of pixels PX in the display area DA and connected to the driver chip DIC in the non-display area NDA. The readout lines RL1 to RLh (refer to FIG. 3) are connected to the plurality of sensors FX in the display area DA and connected to the sensor chips SIC1 and SIC2 in the non-display area NDA.

The data lines DL1 to DLm may be divided into a first group and a second group. The first group includes a plurality of first data lines DL_G1, and the second group includes a plurality of second data lines DL_G2. The plurality of first data lines DL_G1 are space apart from each other along the first direction DR1, and the plurality of second data lines DL_G2 are spaced apart from each other along the first direction DR1. The plurality of first data lines DL_G1 are spaced apart from the plurality of second data lines DL_G2 in the first direction DR1.

The plurality of first data lines DL_G1 are connected to pixel driving circuits P_PD of a first group of pixels among the plurality of pixels PX, and the plurality of second data lines DL_G2 are connected to pixel driving circuits P_PD of a second group of pixels among the plurality of pixels PX. The first group of pixels and the first data lines DL_G1 are disposed in a first area A1, and the second group of pixels and the second data lines DL_G2 are disposed in a second area A2. The first area A1 includes a first-first area A1-1 that is on a first side with respect to a center line of the display panel DP that is parallel to the second direction DR2 and a first-second area A1-2 that is on a second side with respect to the center line. The second area A2 includes a second-first area A2-1 disposed between the first-first area A1-1 and the non-display area NDA and a second-second area A2-2 disposed between the first-second area A1-2 and the non-display area NDA.

The plurality of first data lines DL_G1 include first-first data lines DL1-1 in the first-first area A1-1 and first-second data lines DL1-2 in the first-second area A1-2. The plurality of second data lines DL_G2 include second-first data lines DL2-1 in the second-first area A2-1 and second-second data lines DL2-2 in the second-second area A2-2.

The first-first data lines DL1-1 and the first-second data lines DL1-2 are connected to the driver chip DIC. Although FIG. 5A illustrates an example that the first-first data lines DL1-1 and the first-second data lines DL1-2 are connected to the same driver chip DIC, the present disclosure is not limited thereto. For example, the first-first data lines DL1-1 and the first-second data lines DL1-2 may be connected to different driver chips, respectively.

The display panel DP further includes data connecting lines that connect the second data lines DL_G2 to the driver chip DIC. The data connecting lines include a plurality of vertical data connecting lines V_DCL extending in the second direction DR2 along the first data lines DL_G1 and a plurality of horizontal data connecting lines H_DCL extending in the first direction DR1.

The plurality of horizontal data connecting lines H_DCL include first horizontal data connecting lines H_DCL11 to H_DCL13 and second horizontal data connecting lines H_DCL21 to H_DCL23. The first horizontal data connecting lines H_DCL11 to H_DCL13 are connected with the second-first data lines DL2-1, and the second horizontal data connecting lines H_DCL21 to H_DCL23 are connected with the second-second data lines DL2-2. The plurality of vertical data connecting lines V_DCL include first vertical data connecting lines V_DCL1 and second vertical data connecting lines V_DCL2. The first vertical data connecting lines V_DCL1 are connected to the first horizontal data connecting lines H_DCL11 to H_DCL13, and the second vertical data connecting lines V_DCL2 are connected with the second horizontal data connecting lines H_DCL21 to H_DCL23.

Accordingly, the first vertical data connecting lines V_DCL1 are electrically connected with the second-first data lines DL2-1 by the first horizontal data connecting lines H_DCL11 to H_DCL13. The second vertical data connecting lines V_DCL2 are electrically connected with the second-second data lines DL2-2 by the second horizontal data connecting lines H_DCL21 to H_DCL23.

The first vertical data connecting lines V_DCL1 alternate with the first-first data lines DL1-1 in the first-first area A1-1. The second vertical data connecting lines V_DCL2 alternate with the first-second data lines DL1-2 in the first-second area A1-2.

The plurality of horizontal data connecting lines H_DCL and portions of the vertical data connecting lines V_DCL may be in the display area DA. That is, portions of the data connecting lines for connecting the second data lines DL_G2 and the driver chip DIC are disposed in the display area DA. Accordingly, the area of the region occupied by the data connecting lines in the non-display area NDA may be decreased, and thus the area of dead space of the display panel DP may be decreased.

The readout lines RL1 to RLh may be divided into a first group and a second group. The first group includes a plurality of first readout lines RL_G1, and the second group includes a plurality of second readout lines RL_G2. The plurality of first readout lines RL_G1 are spaced apart along the first direction DR1, and the plurality of second readout lines RL_G2 are space apart along the first direction DR1. The plurality of first readout lines RL_G1 are spaced apart from the plurality of second readout lines RL_G2 in the first direction DR1.

The plurality of first readout lines RL_G1 are connected to sensor driving circuits O_SD of a first group of sensors among the plurality of sensors FX, and the plurality of second readout lines RL_G2 are connected to sensor driving circuits O_SD of a second group of sensors among the plurality of sensors FX. The first group of sensors and the first readout lines RL_G1 are in the second area A2, and the second group of sensors and the second readout lines RL_G2 are in the first area A1.

The plurality of first readout lines RL_G1 include first-first readout lines RL1-11 to RL1-13 and first-second readout lines RL1-21 to RL1-23. The first-first readout lines RL1-11 to RL1-23 are in the second-first area A2-1 and connected to the first sensor chip SIC1. The first-second readout lines RL1-21 to RL1-23 are in the second-second area A2-2 and connected to the second sensor chip SIC2.

The plurality of second readout lines RL_G2 include second-first readout lines RL2-11 to RL2-13 and second-second readout lines RL2-21 to RL2-23. The second-first readout lines RL2-11 to RL2-13 are in the first-first area A1-1 and electrically connected to the first sensor chip SIC1. The second-second readout lines RL2-21 to RL2-23 are in the first-second area A1-2 and electrically connected to the second sensor chip SIC2. The plurality of second readout lines RL_G2 may be between the first-first readout lines RL1-11 to RL1-13 and the first-second readout lines RL1-21 to RL1-23.

The display panel DP further includes connecting lines electrically connected with the second readout lines RL_G2. The connecting lines include a plurality of vertical connecting lines V_RL extending in the second direction DR2 along the first readout lines RL_G1 and a plurality of horizontal connecting lines H_RL extending in the first direction DR1. The vertical connecting lines V_RL may include first vertical connecting lines V_RL1 electrically connected to the first sensor chip SIC1 and second vertical connecting lines V_RL2 electrically connected to the second sensor chip SIC2.

The first vertical connecting lines V_RL1 may alternate with the first-first readout lines RL1-11 to RL1-13 in the first direction DR1. The second vertical connecting lines V_RL2 may alternate with the first-second readout lines RL1-21 to RL1-23 in the first direction DR1.

The horizontal connecting lines H_RL electrically connect the vertical connecting lines V_RL to the second readout lines RL_G2. The horizontal connecting lines H_RL include first horizontal connecting lines H_RL1 that respectively connect the first vertical connecting lines V_RL1 to the second-first readout lines RL2-11 to RL2-13, and second horizontal connecting lines H_RL2 that respectively connect the second vertical connecting lines V_RL2 to the second-second readout lines RL2-21 to RL2-23.

The plurality of horizontal connecting lines H_RL and portions of the vertical connecting lines V_RL may be disposed in the display area DA. That is, portions of the connecting lines for connecting the second readout lines RL_G2 and the first and second sensor chips SIC1 and SIC2 are disposed in the display area DA. Accordingly, the area of the region occupied by the connecting lines in the non-display area NDA may be decreased, and thus the area of dead space of the display panel DP may be decreased.

Even though the first or second sensor chip SIC1 or SIC2 is disposed adjacent to the driver chip DIC, the readout lines and the data lines may not cross each other in the non-display area NDA when the second readout lines RL_G2 are connected to the first or second sensor chip SIC1 or SIC2 through the connecting lines and the second data lines DL_G2 are connected to the driver chip DIC through the data connecting lines. Accordingly, coupling capacitance between the readout lines and the data lines may be decreased, and thus the sensing accuracy of the sensors FX may be improved.

Referring to FIG. 5B, the first readout lines RL_G1 and the second readout lines RL_G2 may cross the scan lines SIL1 to SILn, SCL1 to SCLn, SWL1 to SWLn, and SBL1 to SBLn (refer to FIG. 3) and the emission control lines EML1 to EMLn (refer to FIG. 3) that extend in the first direction DR1.

In an embodiment of the present disclosure, the first-first readout lines RL1-11 to RL1-13 may cross the j-th initialization scan line SILj, the j-th compensation scan line SCLj, the j-th write scan line SWLj, the j-th black scan line SBLj, and the j-th emission control line EMLj once. Likewise, the second-first readout lines RL2-11 to RL2-13 may cross the j-th initialization scan line SILj, the j-th compensation scan line SCLj, the j-th write scan line SWLj, the j-th black scan line SBLj, and the j-th emission control line EMLj once.

First coupling capacitance Ccp1 may be formed at the intersection points where the first-first readout lines RL1-11 to RL1-13 cross the scan lines SIL1 to SILn, SCL1 to SCLn, SWL1 to SWLn, and SBL1 to SBLn and the emission control lines EML1 to EMLn, and second coupling capacitance Ccp2 may be formed at the intersection points where the second-first readout lines RL2-11 to RL2-13 cross the scan lines SIL1 to SILn, SCL1 to SCLn, SWL1 to SWLn, and SBL1 to SBLn and the emission control lines EML1 to EMLn.

In an embodiment of the present disclosure, the second-first readout lines RL2-11 to RL2-13 are connected to the first vertical connecting lines V_RL1 through the first horizontal connecting lines H_RL1. Since the first horizontal connecting lines H_RL1 extend in the first direction DR1, the first horizontal connecting lines H_RL1 do not cross the j-th initialization scan line SILj, the j-th compensation scan line SCLj, the j-th write scan line SWLj, the j-th black scan line SBLj, and the j-th emission control line EMLj. However, since the first vertical connecting lines V_RL1 extend in the second direction DR2, the first vertical connecting lines V_RL1 may cross the j-th initialization scan line SILj, the j-th compensation scan line SCLj, the j-th write scan line SWLj, the j-th black scan line SBLj, and the j-th emission control line EMLj. Accordingly, third coupling capacitance Ccp3 may be formed at the intersection points where the first vertical connecting lines V_RL1 cross the scan lines SIL1 to SILn, SCL1 to SCLn, SWL1 to SWLn, and SBL1 to SBLn and the emission control lines EML1 to EMLn.

Thus, only the first coupling capacitance Ccp1 may act on the first-first readout lines RL1-11 to RL1-13, but the second coupling capacitance Ccp2 and the third coupling capacitance Ccp3 may act on the second-first readout lines RL2-11 to RL2-13. The difference between the coupling capacitance acting on the second-first readout lines RL2-11 to RL2-12 and the coupling capacitance acting on the first-first readout lines RL1-11 to RL1-13 may be reduced when the third coupling capacitance Ccp3 is decreased.

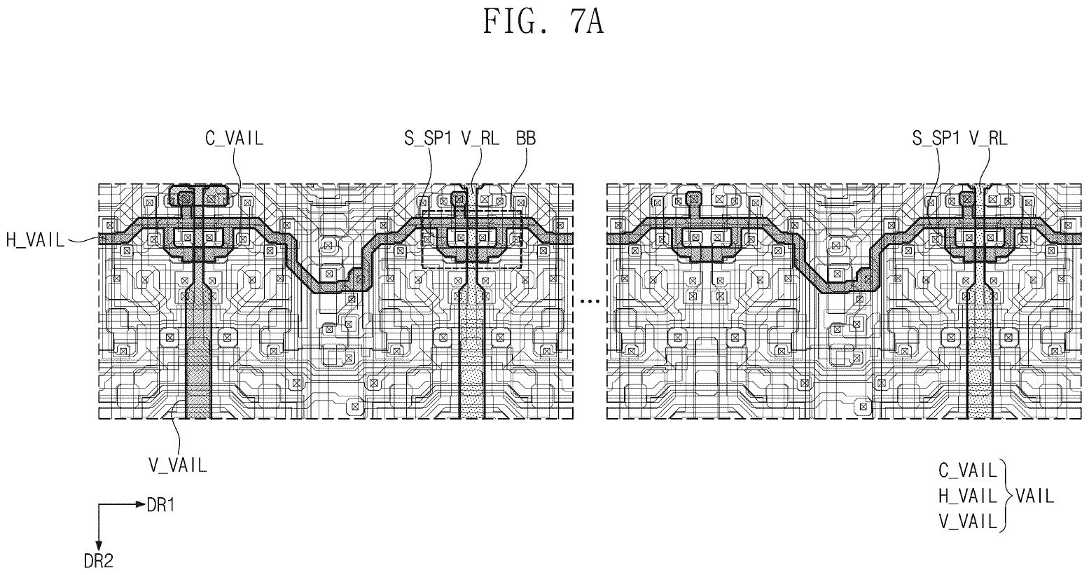

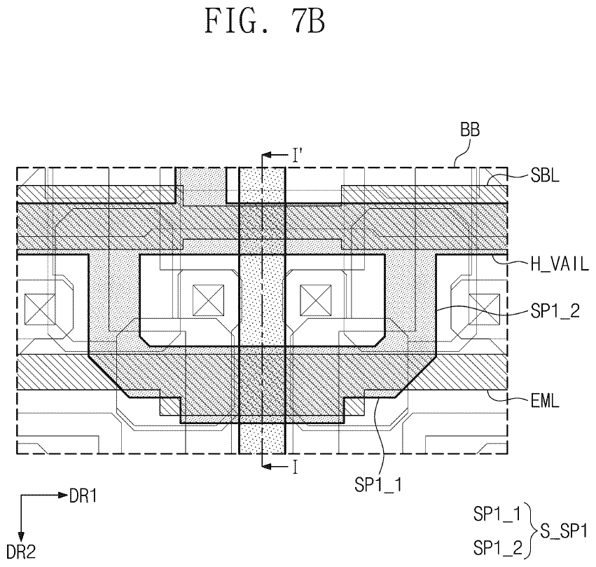

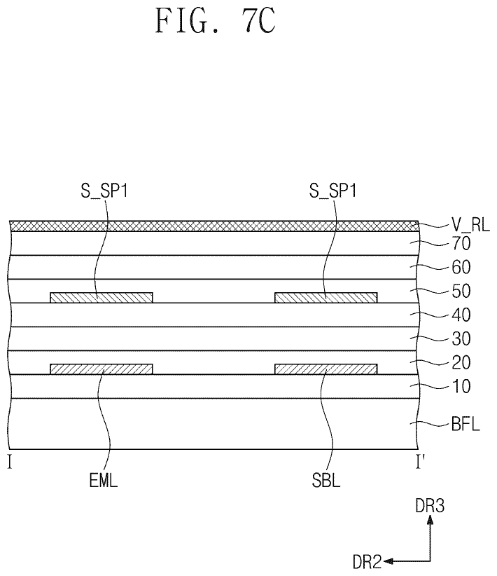

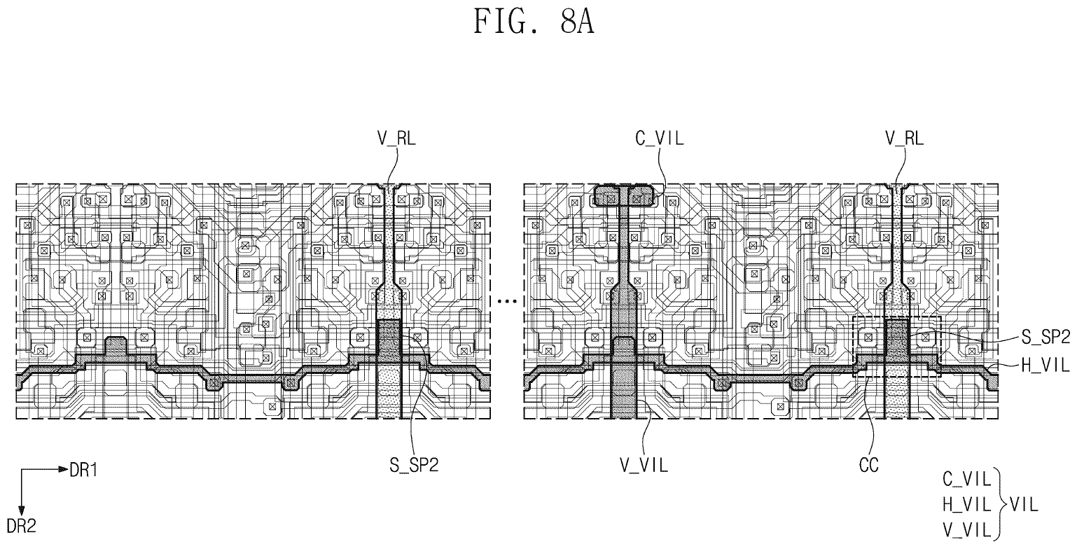

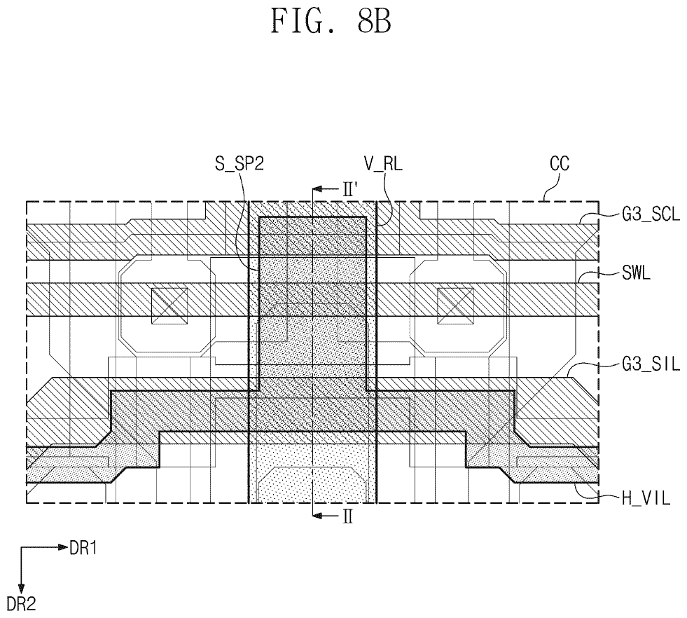

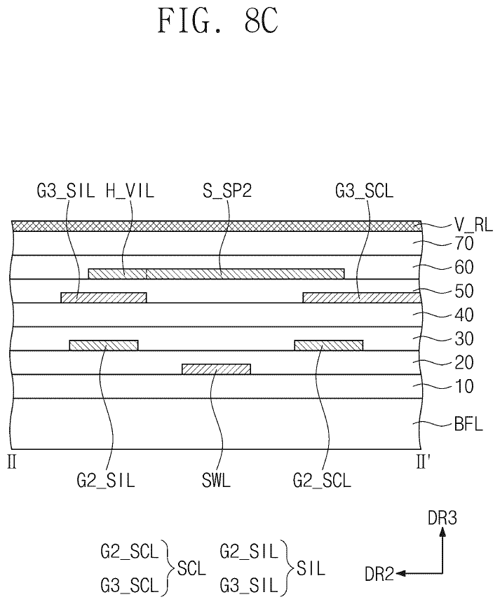

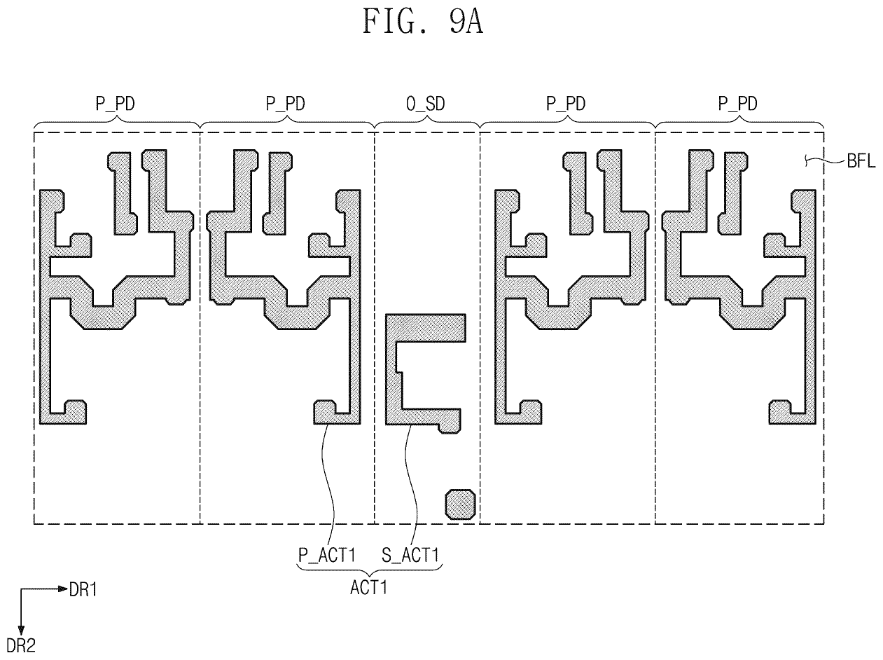

A method of decreasing the third coupling capacitance Ccp3 by applying a shielding pattern is described below with reference to FIGS. 7A to 8C.

FIG. 6 is a sectional view of the display panel according to an embodiment of the present disclosure.

Referring to FIG. 6, the display panel DP may include the base layer BL, the circuit layer DP_CL, and the element layer DP_ED.

The base layer BL may include a synthetic resin layer. The synthetic resin layer may include a thermosetting resin. In particular, the synthetic resin layer may be a polyimide-based resin layer, but the material thereof is not particularly limited. The synthetic resin layer may include at least one of an acrylic resin, a methacrylic resin, a polyisoprene resin, a vinyl resin, an epoxy resin, a urethane-based resin, a celluosic resin, a siloxane-based resin, a polyamide resin, or a perylene-based resin. In addition, the base layer BL may include a glass substrate, a metal substrate, or an organic/inorganic composite substrate.

At least one inorganic layer is formed on the upper surface of the base layer BL. The inorganic layer may include at least one of aluminum oxide, titanium oxide, silicon oxide, silicon oxy nitride, zirconium oxide, or hafnium oxide. The inorganic layer may be formed of multiple layers. The multiple inorganic layers may constitute a barrier layer BRL and/or a buffer layer BFL that are described below. The barrier layer BRL and the buffer layer BFL may be selectively disposed or patterned.

The circuit layer DP_CL may include the barrier layer BRL and/or the buffer layer BFL. The barrier layer BRL prevents infiltration of foreign matter from the base layer or otherwise outside the display panel DP. The barrier layer BRL may include a silicon oxide layer and a silicon nitride layer. A plurality of silicon oxide layers and a plurality of silicon nitride layers may be provided. The silicon oxide layers and the silicon nitride layers may be alternately stacked one above another.

The buffer layer BFL may be disposed on the barrier layer BRL. The buffer layer BFL may improve the coupling force between the base layer BL and a semiconductor pattern and/or a conductive pattern in the circuit layer DP_CL. The buffer layer BFL may include silicon oxide layers and silicon nitride layers. The silicon oxide layers and the silicon nitride layers may be alternately stacked one above another.

The semiconductor pattern is on the buffer layer BFL. Hereinafter, the semiconductor pattern directly on the buffer layer BFL or otherwise closest to the base layer BL is referred to as a first semiconductor pattern. The first semiconductor pattern may include a silicon semiconductor. The first semiconductor pattern may include polysilicon. However, without being limited thereto, the first semiconductor pattern may include amorphous silicon.

FIG. 6 merely illustrates a portion of the first semiconductor pattern, and the first semiconductor pattern may be additionally in another area of the pixel PXij (refer to FIG. 4A) or other pixels PX or sensors FX. The first semiconductor pattern may have different electrical properties depending on whether or not an area of the first semiconductor pattern is doped. The first semiconductor pattern may include a doped area and a non-doped area. The doped area may be doped with an N-type dopant or a P-type dopant. A P-type transistor includes a doped area doped with a P-type dopant, and an N-type transistor includes a doped area doped with an N-type dopant.

The doped area has a higher conductivity than the non-doped area and may serve as an electrode or a signal line. The non-doped area substantially may correspond to an active area (or, a channel) of a transistor. In other words, one portion of the first semiconductor pattern may be the active area of the transistor, another portion may be a source or drain of the transistor, and another portion may be a connecting signal line or a connecting electrode.

As illustrated in FIG. 6, a first electrode S1, a channel part A1, and a second electrode D1 of the first transistor T1 may be formed in the first semiconductor pattern. The first electrode S1 and the second electrode D1 of the first transistor T1 extend from the channel part A1 in opposite directions.

In FIG. 6, a portion of a connecting signal line CSL formed from the semiconductor pattern is illustrated. Although not separately illustrated, the connecting signal line CSL may be connected to the second electrode of the sixth transistor T6 (refer to FIG. 4A) when viewed from above the plane.

A first insulating layer 10 is on the buffer layer BFL. The first insulating layer 10 commonly overlaps the plurality of pixels PX (refer to FIG. 3) and covers the first semiconductor pattern. The first insulating layer 10 may be an inorganic layer and/or an organic layer and may have a single-layer structure or a multi-layer structure. The first insulating layer 10 may include at least one of aluminum oxide, titanium oxide, silicon oxide, silicon oxynitride, zirconium oxide, or hafnium oxide. In an example embodiment, the first insulating layer 10 may be a single silicon oxide layer. Not only the first insulating layer 10 but also insulating layers of the circuit layer DP_CL that are described below may be inorganic layers and/or organic layers, and each may have a single-layer structure or a multi-layer structure. The inorganic layers may include at least one of the aforementioned materials.

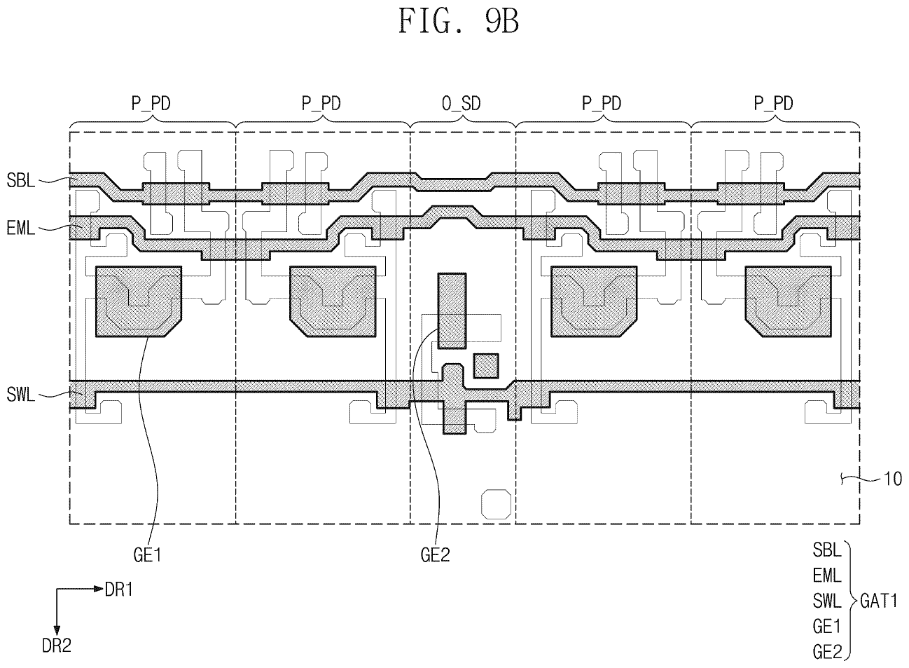

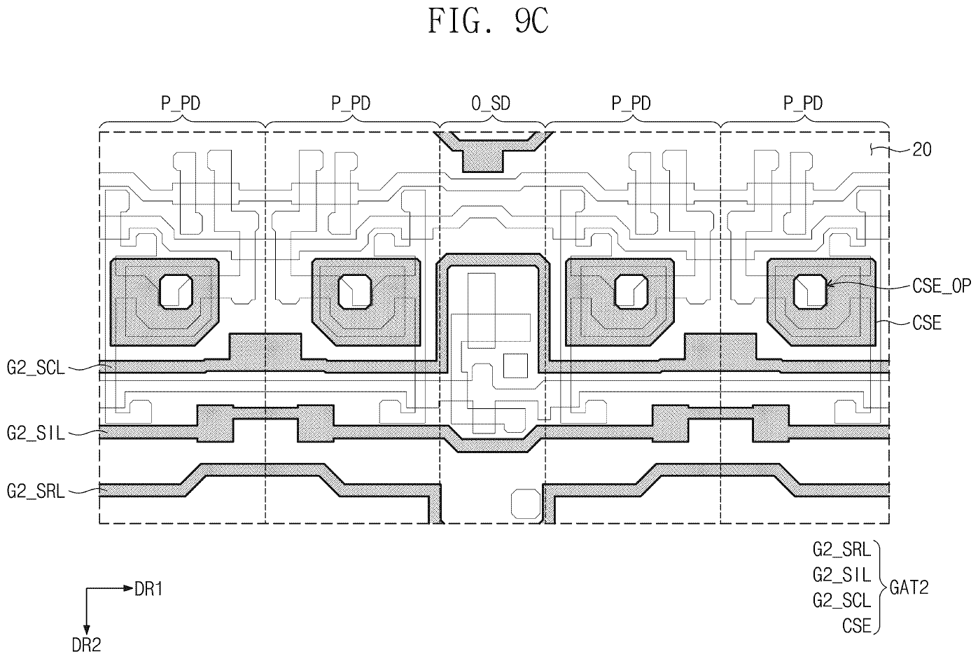

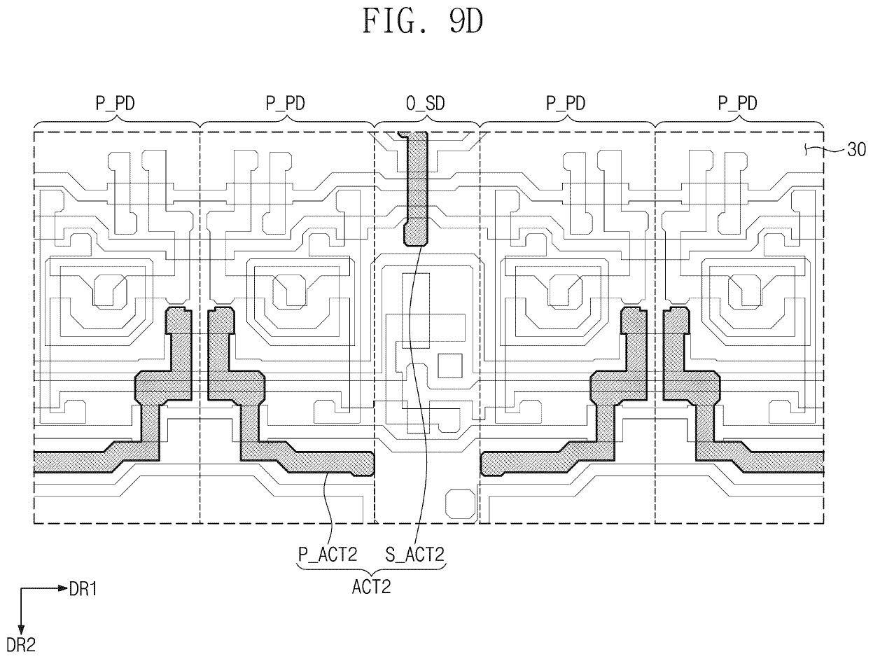

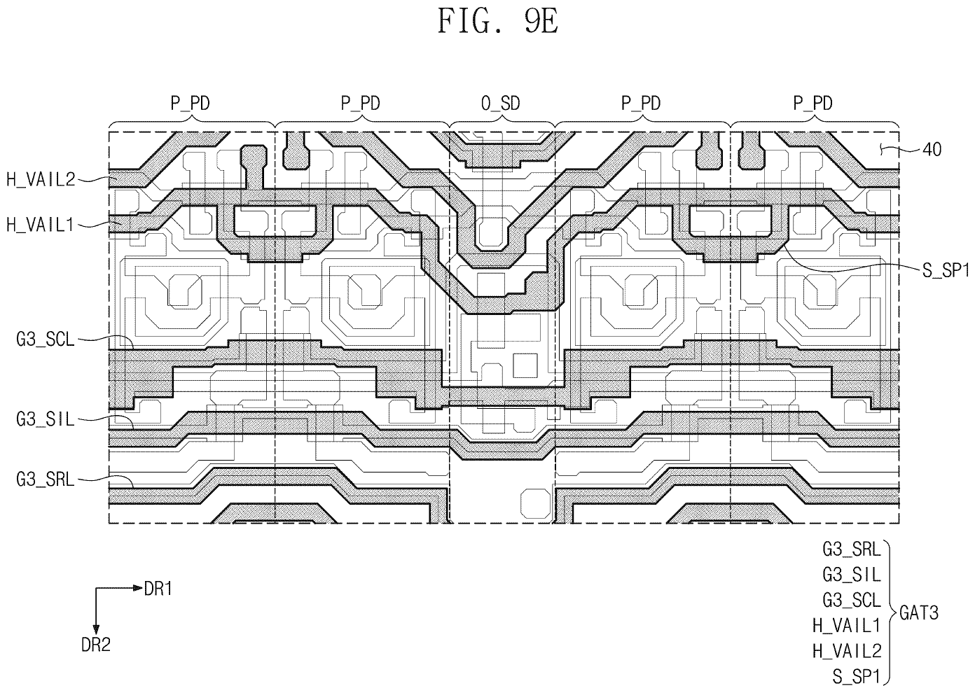

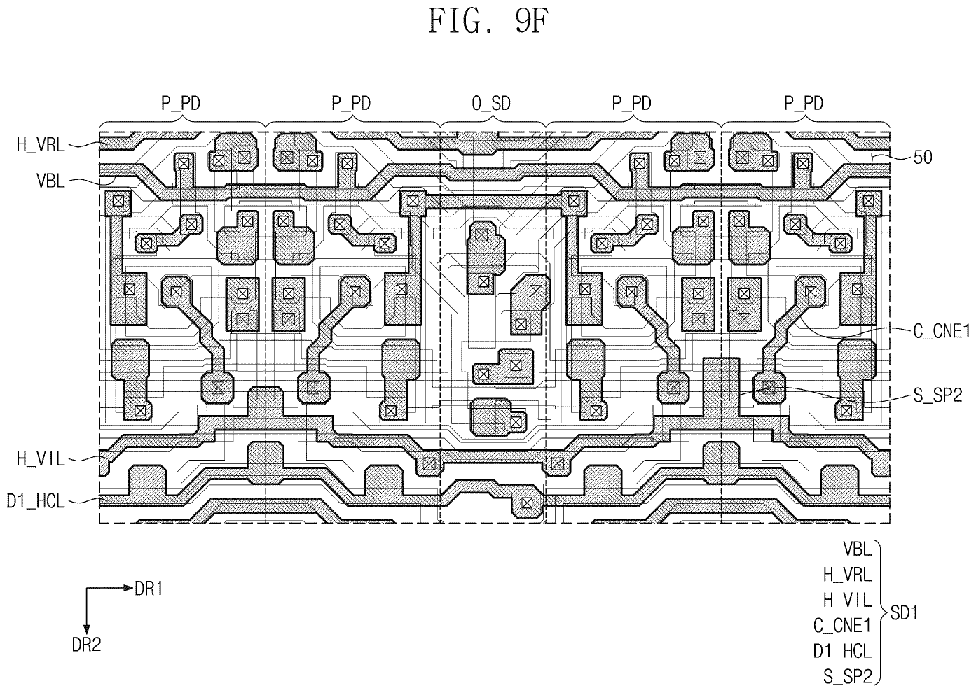

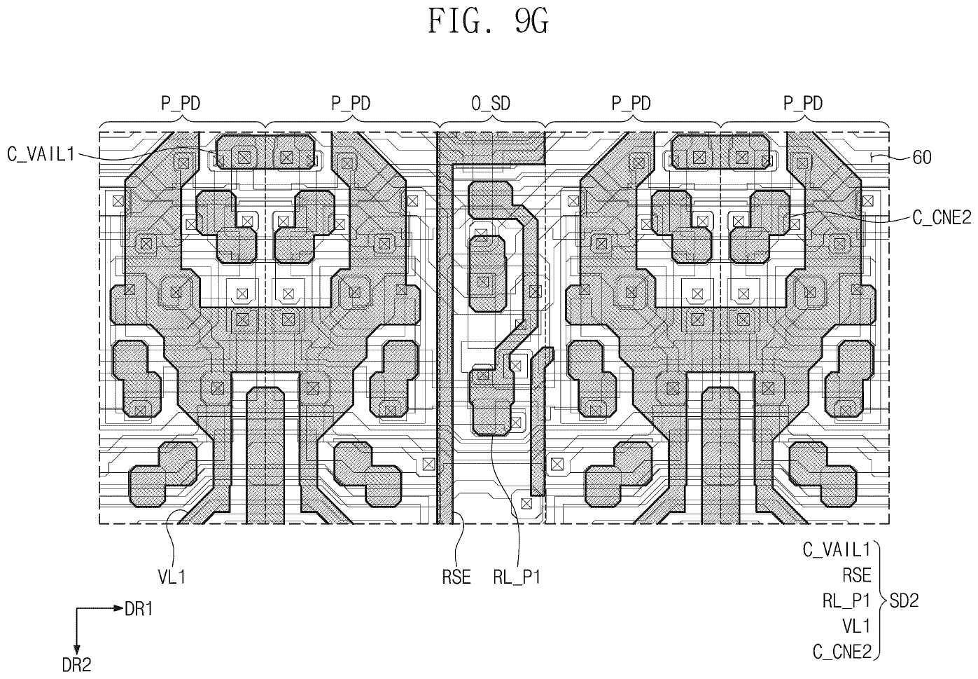

The third electrode G1 of the first transistor T1 is disposed on the first insulating layer 10. The third electrode G1 may be a portion of a first gate pattern layer GAT1 (refer to FIG. 9B). The third electrode G1 of the first transistor T1 overlaps the channel part A1 of the first transistor T1. The third electrode G1 of the first transistor T1 may serve as a mask in a process of doping the first semiconductor pattern.

A second insulating layer 20 that covers the third electrode G1 is on the first insulating layer 10. The second insulating layer 20 commonly overlaps the plurality of pixels PX. The second insulating layer 20 may be an inorganic layer and/or an organic layer and may have a single-layer structure or a multi-layer structure. In the example embodiment, the second insulating layer 20 may be a single silicon oxide layer.

An upper electrode UE may be on the second insulating layer 20. The upper electrode UE may overlap the third electrode G1. The upper electrode UE may a portion of a second gate pattern layer GAT2 (refer to FIG. 9C) or may be a portion of a doped semiconductor pattern. A portion of the third electrode G1 and the upper electrode UE overlapping the portion of the third electrode G1 may define the capacitor Cst (refer to FIG. 4A). In an embodiment of the present disclosure, the upper electrode UE may be omitted.

In an embodiment of the present disclosure, the second insulating layer 20 may be replaced with an insulating pattern, and the upper electrode UE may be on the insulating pattern. The upper electrode UE may serve as a mask during a process that forms the insulating pattern from the second insulating layer 20.

A third insulating layer 30 that covers the upper electrode UE is on the second insulating layer 20. In the example embodiment, the third insulating layer 30 may be a single silicon oxide layer. A semiconductor pattern is on the third insulating layer 30. Hereinafter, the semiconductor pattern directly on the third insulating layer 30 may be referred to as a second semiconductor pattern. The second semiconductor pattern may include metal oxide semiconductor. The oxide semiconductor may include a crystalline or amorphous oxide semiconductor. For example, the oxide semiconductor may include metal oxide of zinc (Zn), indium (In), gallium (Ga), tin (Sn), or titanium (Ti). Alternatively, the oxide semiconductor may include a mixture of metal such as zinc (Zn), indium (In), gallium (Ga), tin (Sn), or titanium (Ti) and oxide thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), or zinc-tin oxide (ZTO).

FIG. 6 merely illustrates a portion of the second semiconductor pattern, and the second semiconductor pattern may be additionally disposed in another area of the pixel PXij and other pixels PX or sensors FX. The second semiconductor pattern may include a plurality of areas distinguished depending on whether metal oxide is reduced or not. An area where metal oxide is reduced (hereinafter, referred to as the reduced area) has a higher conductivity than an area where metal oxide is not reduced (hereinafter, referred to as the non-reduced area). The reduced area may serve as an electrode or a signal line. The non-reduced area substantially may correspond to a channel part of a transistor. In other words, one portion of the second semiconductor pattern may be the channel part of a transistor, and another portion may be a first electrode or a second electrode of the transistor.

The circuit layer DP_CL may further include a portion of a semiconductor pattern of the sensor driving circuit O_SD (refer to FIG. 4A). For convenience of description, the reset transistor ST1 of the semiconductor pattern of the sensor driving circuit O_SD is illustrated in FIG. 6. The first electrode STS1, a channel part STA1, and the second electrode STD1 of the reset transistor ST1 may be formed in the second semiconductor pattern. In an embodiment of the present disclosure, the second semiconductor pattern may include metal oxide. The first electrode STS1 and the second electrode STD1 include metal reduced from a metal oxide semiconductor. The first electrode STS1 and the second electrode STD1 may include a metal layer that has a certain thickness from the upper surface of the second semiconductor pattern and includes the reduced metal.

A fourth insulating layer 40 covers the first electrode STS1, the channel part STA1, and the second electrode STD1 of the reset transistor ST1. The third electrode STG1 of the reset transistor ST1 is on the fourth insulating layer 40. In this embodiment, the third electrode STG1 may be a portion of a third gate pattern layer GAT3 (refer to FIG. 9E). The third electrode STG1 of the reset transistor ST1 overlaps the channel part STA1 of the reset transistor ST1. Although one third electrode STG1 is illustrated in this embodiment for convenience of description, the reset transistor ST1 may include two or more third electrodes.

A fifth insulating layer 50 that covers the third electrode G3 is on the fourth insulating layer 40. In this embodiment, the fifth insulating layer 50 may include a silicon oxide layer and a silicon nitride layer. The fifth insulating layer 50 may include a plurality of silicon oxide layers and a plurality of silicon nitride layers alternately stacked one above another.

At least one insulating layer is additionally disposed on the fifth insulating layer 50. In this embodiment, a sixth insulating layer 60 and a seventh insulating layer 70 may be disposed on the fifth insulating layer 50. The sixth insulating layer 60 and the seventh insulating layer 70 may be organic layers and may have a single-layer structure or a multi-layer structure. Each of the sixth insulating layer 60 and the seventh insulating layer 70 may be a single polyimide-based resin layer. Without being limited thereto, the sixth insulating layer 60 and the seventh insulating layer 70 may include at least one of an acrylic resin, a methacrylic resin, a polyisoprene resin, a vinyl resin, an epoxy resin, a urethane-based resin, a celluosic resin, a siloxane-based resin, a polyamide resin, or a perylene-based resin.

A first connecting electrode CNE10 may be on the fifth insulating layer 50. The first connecting electrode CNE10 connects to the connecting signal line CSL through a first contact hole CH1 penetrating the first to fifth insulating layers 10 to 50. A second connecting electrode CNE20 on the sixth insulating layer 60 may connect to the first connecting electrode CNE10 through a second contact hole CH2 penetrating the sixth insulating layer 60. In an embodiment of the present disclosure, at least one of the fifth to seventh insulating layers 50 to 70 may be omitted, and one of the first and second connecting electrodes CNE10 and CNE20 may also be omitted.

A third connecting electrode CNE11 may be on the fifth insulating layer 50. The third connecting electrode CNE11 connects to the second electrode STD1 of the reset transistor ST1 through a third contact hole CH3 penetrating the fourth and fifth insulating layers 40 and 50. A fourth connecting electrode CNE21 may connect to the third connecting electrode CNE11 through a fourth contact hole CH4 penetrating the sixth insulating layer 60.

The first and third connecting electrodes CNE10 and CNE11 may be portions of a first data metal pattern, and the second and fourth connecting electrodes CNE20 and CNE21 may be portions of a second data metal pattern.

The horizontal data connecting lines H_DCL (refer to FIG. 5) may be disposed on the same layer as the first and third connecting electrodes CNE10 and CNE11 (that is, on the fifth insulating layer 50). However, the present disclosure is not limited thereto. The horizontal data connecting lines H_DCL may be disposed on the same layer (that is, on the first insulating layer 10) as the third electrode G1 of the first transistor T1.

A portion (that is, a first line portion RL_P1) of a readout wiring RL may be on the same layer (that is, on the sixth insulating layer 60) as the second and fourth connecting electrodes CNE20 and CNE21. The readout wiring RL may be one of the readout lines RL1 to RLh illustrated in FIG. 3. The second and fourth connecting electrodes CNE20 and CNE21 and the first line portion RL_P1 of the readout wiring RL are covered by the seventh insulating layer 70.

A data wiring DL, the vertical data connecting lines V_DCL (refer to FIG. 5A), a vertical reset voltage line V_VRL, the vertical connecting lines V_RL (refer to FIG. 7A), and a portion (that is, a second line portion RL_P2) of the readout wiring RL may be disposed on the seventh insulating layer 70. The data wiring DL may be one of the data lines DL1 to DLm illustrated in FIG. 3. The vertical reset voltage line V_VRL may be a component included in the reset voltage line VRL illustrated in FIG. 4A.

A fifth connecting electrode CNE30 and a sixth connecting electrode CNE31 may be on the seventh insulating layer 70. The fifth connecting electrode CNE30 may connect to the second connecting electrode CNE20 through a fifth contact hole CH5 penetrating the seventh insulating layer 70. The sixth connecting electrode CNE31 may connect to the fourth connecting electrode CNE21 through a sixth contact hole CH6 penetrating the seventh insulating layer 70.

The data wiring DL, the vertical data connecting lines V_DCL, the vertical connecting lines V_RL, the vertical reset voltage line V_VRL, and the second line portion RL_P2 may be on the same layer as the fifth connecting electrode CNE30 and the sixth connecting electrode CNE31 but may be electrically insulated from the fifth connecting electrode CNE30 and the sixth connecting electrode CNE31. An eighth insulating layer 80 may cover the data wiring DL, the vertical data connecting lines V_DCL, the vertical connecting lines V_RL, the vertical reset voltage line V_VRL, the second line portion RL_P2, the fifth connecting electrode CNE30, and the sixth connecting electrode CNE31.

The element layer DP_ED is on the circuit layer DP_CL. The element layer DP_ED may include the anode electrode P_AE of the light emitting element ED (refer to FIG. 4A) and the anode electrode O_AE of the light receiving element OPD (refer to FIG. 4A). As illustrated in FIG. 6, the anode electrode P_AE of the light emitting element ED may connect to the fifth connecting electrode CNE30 through a seventh contact hole CH7 penetrating the eighth insulating layer 80. The anode electrode O_AE of the light receiving element OPD may connect to the sixth connecting electrode CNE31 through an eighth contact hole CH8 penetrating the eighth insulating layer 80.

Although FIG. 6 illustrates a structure in which the circuit layer DP_CL includes the fifth connecting electrode CNE30 and the sixth connecting electrode CNE31, the present disclosure is not limited thereto. Alternatively, the fifth connecting electrode CNE30 and the sixth connecting electrode CNE31 may be omitted from the circuit layer DP_CL. In this case, the anode electrode P_AE may be directly connected with the second connecting electrode CNE20, and the anode electrode O_AE may be directly connected with the fourth connecting electrode CNE21.

The element layer DP_ED further includes a pixel defining layer PDL disposed on the circuit layer DP_CL. The pixel defining layer PDL may include a light emitting opening OP1 that correspond to the light emitting element ED and a light receiving opening OP2 that correspond to the light receiving element OPD. The light emitting opening OP1 exposes at least a portion of the anode electrode P_AE of the light emitting element ED. The light emitting opening OP1 of the pixel defining layer PDL may define an emissive area PXA. For example, the plurality of pixels PX (refer to FIG. 3) may be arranged on the plane of the display panel DP (refer to FIG. 3) according to a certain rule for placement of openings in the pixel defining layer PDL. Areas where the plurality of pixels PX are disposed may be defined as pixel areas, and one pixel area may include an emissive area PXA and a non-emissive area NPXA adjacent to the emissive area PXA. The non-emissive area NPXA may surround the emissive area PXA.

The light receiving opening OP2 overlaps the anode electrode O_AE of the light receiving element OPD. The light receiving opening OP2 of the pixel defining layer PDL may define a light receiving area SA. For example, the plurality of sensors FX (refer to FIG. 3) may be arranged on the plane of the display layer DP according to a certain rule for placement of openings in the pixel defining layer PDL. Areas where the plurality of sensors FX are disposed may be defined as sensing areas, and one sensing area may include a light receiving area SA and a non-light receiving area NSA adjacent to the light receiving area SA. The non-light receiving area NSA may surround the light receiving area SA.

An emissive layer P_EL is disposed to correspond to the light emitting opening OP1 defined in the pixel defining layer PDL, and a photoelectric conversion layer O_RL is disposed to correspond to the light receiving opening OP2 defined in the pixel defining layer PDL. Although the patterned emissive layer P_EL is illustrated in this embodiment, the present disclosure is not limited thereto. A common emissive layer may be commonly disposed in the plurality of pixels PX. In this case, the common emissive layer may generate white light or blue light. The common cathode electrode C_CE is commonly connected to the light emitting element ED and the light receiving element OPD. The common cathode electrode C_CE may face the anode electrode O_AE and the anode electrode P_AE. The common cathode electrode C_CE is on the emissive layer P_EL and the photoelectric conversion layer O_RL. The common cathode electrode C_CE may be commonly disposed in the plurality of pixels PX and the plurality of sensors FX.

FIG. 7A is a plan view illustrating a portion of the display panel according to an embodiment of the present disclosure, and FIG. 7B is an enlarged view of portion BB of FIG. 7A. FIG. 7C is a sectional view taken along line I-I′ illustrated in FIG. 7B.

Each of conductive patterns and semiconductor patterns of the display panel DP may have a structure that is repeated across an area of the display panel DP according to a certain rule, and FIG. 7A illustrates some structures of the pixel driving circuits P_PD and the sensor driving circuits O_SD that may be repeated.

Referring to FIG. 7A, a voltage line have a mesh shape in the display area DA (refer to FIG. 5A) of the display panel DP (refer to FIG. 5A). In an embodiment of the present disclosure, the first driving voltage line VL1, the second driving voltage line VL2, and the first and second initialization voltage lines VIL and VAIL illustrated in FIG. 4A may have a mesh shape formed by connecting horizontal lines and vertical lines. Although one voltage line (that is, the second initialization voltage line VAIL) is illustrated as an example in FIG. 7A, the present disclosure is not limited thereto.

The second initialization voltage line VAIL includes a second horizontal initialization voltage line H_VAIL and a second vertical initialization voltage line V_VAIL. The second horizontal initialization voltage line H_VAIL extends in the first direction DR1, and the second vertical initialization voltage line V_VAIL extends in the second direction DR2. Accordingly, the second initialization voltage line VAIL may include a mesh shape in the display area DA of the display panel DP.

The second horizontal initialization voltage line H_VAIL and the second vertical initialization voltage line V_VAIL may be on different layers of the circuit layer DP_CL. For example, the second horizontal initialization voltage line H_VAIL may be on the fourth insulating layer 40 (refer to FIG. 6), and the second vertical initialization voltage line V_VAIL may be on the seventh insulating layer 70 (refer to FIG. 6). The second initialization voltage line VAIL may further include a second initialization connecting pattern C_VAIL for connecting the second horizontal initialization voltage line H_VAIL and the second vertical initialization voltage line V_VAIL. In an embodiment of the present disclosure, the second initialization connecting pattern C_VAIL may be on the sixth insulating layer 60 (refer to FIG. 6). The second horizontal initialization voltage line H_VAIL may be connected to the second vertical initialization voltage line V_VAIL through the second initialization connecting pattern C_VAIL.

The vertical connecting lines V_RL electrically connected with the second readout lines RL_G2 (refer to FIG. 5A) extend in the second direction DR2. The vertical connecting lines V_RL may extend parallel to the second vertical initialization voltage line V_VAIL.

The vertical connecting lines V_RL may cross at least one gate wiring. In an embodiment of the present disclosure, each of the vertical connecting lines V_RL may cross a first gate wiring SBL, a second gate wiring EML, a third gate wiring SWL, and a fourth gate wiring SCL. The first gate wiring SBL may be one of the black scan lines SBL1 to SBLn illustrated in FIG. 3, and the second gate wiring EML may be one of the emission control lines EML1 to EMLn illustrated in FIG. 3. The third gate wiring SWL may be one of the write scan lines SWL1 to SWLn illustrated in FIG. 3, and the fourth gate wiring SCL may be one of the compensation scan lines SCL1 to SCLn illustrated in FIG. 3.

To decrease the third coupling capacitance Ccp3, the display panel DP includes the shielding pattern disposed in the area where each of the vertical connecting lines V_RL crosses at least one of the first to fourth gate wirings SBL, EML, SWL, and SCL. In an embodiment of the present disclosure, the shielding pattern may include a first shielding pattern S_SP1 extending from the second horizontal initialization voltage line H_VAIL. In an embodiment shown in FIG. 7B, the first shielding pattern S_SP1 may include a first shielding portion SP1_1 parallel to the first direction DR1 and a second shielding portion SP1_2 parallel to the second direction DR2. The first shielding portion SP1_1 of the first shielding pattern S_SP1 overlaps the vertical connecting lines V_RL, the first gate wiring SBL, and the second gate wiring EML when viewed from above the plane and is disposed between the vertical connecting lines V_RL and the first and second gate wirings SBL and EML in the normal direction perpendicular to the plane.

The first shielding pattern S_SP1 may have the same potential (that is, the second initialization voltage Vaint) as the second horizontal initialization voltage line H_VAIL. Since the second initialization voltage Vaint is a DC voltage, the first shielding pattern S_SP1 may have a constant potential.

Referring to FIG. 7C, the first and second gate wirings SBL and EML are disposed on the first insulating layer 10. The second to fourth insulating layers 20, 30, and 40 are sequentially stacked on the first and second gate wirings SBL and EML. The second horizontal initialization voltage line H_VAIL and the first shielding pattern S_SP1 are disposed on the fourth insulating layer 40. The first shielding pattern S_SP1 may face the first and second gate wirings SBL and EML with the second to fourth insulating layers 20, 30, and 40 therebetween.

The fifth to seventh insulating layers 50, 60, and 70 are sequentially stacked on the second horizontal initialization voltage line H_VAIL and the first shielding pattern S_SP1. The vertical connecting lines V_RL are on the seventh insulating layer 70. The vertical connecting lines V_RL may face the first shielding pattern S_SP1 with the fifth to seventh insulating layers 50, 60, and 70 therebetween. That is, the first shielding pattern S_SP1 may be between the vertical connecting lines V_RL and the first and second gate wirings SBL and EML in the third direction DR3. The third coupling capacitance formed between the vertical connecting lines V_RL and the first and second gate wirings SBL and EML may be decreased by the first shielding pattern S_SP1 having the constant potential, and thus a deviation in coupling capacitance between the first and second readout lines RL_G1 and RL_G2 may be decreased. Accordingly, deterioration in the sensing accuracy of the sensor FX (refer to FIG. 3) due to a deviation in coupling capacitance may be prevented.

FIG. 8A is a plan view illustrating a portion of the display panel according to an embodiment of the present disclosure, and FIG. 8B is an enlarged view of portion CC of FIG. 8A. FIG. 8C is a sectional view taken along line II-II′ illustrated in FIG. 8B.

Referring to FIG. 8A, the first initialization voltage line VIL includes a first horizontal initialization voltage line H_VIL and a first vertical initialization voltage line V_VIL. The first horizontal initialization voltage line H_VIL extends in the first direction DR1, and the first vertical initialization voltage line V_VIL extends in the second direction DR2. Accordingly, the first initialization voltage line VIL may have a mesh shape in the display area DA (refer to FIG. 3) of the display panel DP (refer to FIG. 3).

The first horizontal initialization voltage line H_VIL and the first vertical initialization voltage line V_VIL may be on different layers of the circuit layer DP_CL (refer to FIG. 6). For example, the first horizontal initialization voltage line H_VIL may be on the fifth insulating layer 50 (refer to FIG. 6), and the first vertical initialization voltage line V_VIL may be on the seventh insulating layer 70 (refer to FIG. 6). The first initialization voltage line VIL may further include a first initialization connecting pattern C_VIL for connecting the first horizontal initialization voltage line H_VIL and the first vertical initialization voltage line V_VIL. In an embodiment of the present disclosure, the first initialization connecting pattern C_VIL may be on the sixth insulating layer 60 (refer to FIG. 6). The first horizontal initialization voltage line H_VIL may be connected to the first vertical initialization voltage line V_VIL through the first initialization connecting pattern C_VIL.

In an embodiment of the present disclosure, the shielding pattern may further include a second shielding pattern S_SP2 extending from the first horizontal initialization voltage line H_VIL in the direction opposite to the second direction DR2. Accordingly, the second shielding pattern S_SP2 may have the same potential (that is, the first initialization voltage Vint) as the first horizontal initialization voltage line H_VIL. Since the first initialization voltage Vint is a DC voltage, the second shielding pattern S_SP2 may have a constant potential.

The second shielding pattern S_SP2, as shown in FIG. 8B, overlaps the vertical connecting lines V_RL, the third gate wiring SWL, and the fourth gate wiring SCL when viewed from above the plane and is between the vertical connecting lines V_RL and the third and fourth gate wirings SWL and SCL in the normal direction perpendicular to the plane.

Referring to FIG. 8C, the third gate wiring SWL is on the first insulating layer 10. The fourth gate wiring SCL includes a fourth-first gate wiring G2_SCL disposed on the second insulating layer 20 and a fourth-second gate wiring G3_SCL on the fourth insulating layer 40.

The third and fourth insulating layers 30 and 40 are sequentially stacked on the fourth-first gate wiring G2_SCL, and the fifth insulating layer 50 is on the fourth-second gate wiring G3_SCL. The first horizontal initialization voltage line H_VIL and the second shielding pattern S_SP2 are on the fifth insulating layer 50. The second shielding pattern S_SP2 may face the third gate wiring SWL and the fourth-second gate wiring G3_SCL with the fifth insulating layer 50 therebetween.

The sixth and seventh insulating layers 60 and 70 are sequentially stacked on the first horizontal initialization voltage line H_VIL and the second shielding pattern S_SP2. The vertical connecting lines V_RL are on the seventh insulating layer 70. The vertical connecting lines V_RL may face the second shielding pattern S_SP2 with the sixth and seventh insulating layers 60 and 70 therebetween. That is, the second shielding pattern S_SP2 may be between the vertical connecting lines V_RL and the third gate wiring SWL and the fourth-second gate wiring G3_SCL in the third direction DR3.

In an embodiment of the present disclosure, the first horizontal initialization voltage line H_VIL may overlap a fifth gate wiring SIL when viewed from above the plane. The fifth gate wiring SIL includes a fifth-first gate wiring G2_SIL on the second insulating layer 20 and a fifth-second gate wiring G3_SIL on the fourth insulating layer 40. That is, the first horizontal initialization voltage line H_VIL may be between the vertical connecting lines V_RL and the fifth-second gate wiring G3_SIL in the third direction DR3.

The third coupling capacitance Ccp3 formed between the vertical connecting lines V_RL and the third gate wiring SWL and the fourth-second gate wiring G3_SCL may be decreased by the second shielding pattern S_SP2 having the constant potential, and thus a deviation in coupling capacitance between the first and second readout lines RL_G1 and RL_G2 may be decreased. Accordingly, deterioration in the sensing accuracy of the sensor FX (refer to FIG. 3) due to a deviation in coupling capacitance may be prevented.

FIGS. 9A to 9H are plan views illustrating an arrangement order of circuit layers according to an embodiment of the present disclosure.

Referring to FIGS. 9A to 9H, each of conductive patterns and semiconductor patterns may have a structure that is repeated across the area of the circuit layer DP_CL according to a certain rule when viewed from above the plane. FIGS. 9A to 9H show some of the pixel driving circuits P_PD and some of the sensor driving circuits O_SD.

Referring to FIG. 9A, a first semiconductor pattern layer ACT1 may be on the buffer layer BFL. The first semiconductor pattern layer ACT1 may include a silicon semiconductor. For example, the silicon semiconductor may include amorphous silicon or polycrystalline silicon. For example, the first semiconductor pattern layer ACT1 may include low-temperature polycrystalline silicon (LTPS).

The first semiconductor pattern layer ACT1 includes a first semiconductor pattern P_ACT1 included in the pixel driving circuit P_PD and a second semiconductor pattern S_ACT1 included in the sensor driving circuit O_SD.

Referring to FIG. 9B, the first gate pattern layer GAT1 may be on the first insulating layer 10. The first gate pattern layer GAT1 may include metal, an alloy, conductive metal oxide, or a transparent conductive material. For example, the first gate pattern layer GAT1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), or indium zinc oxide (IZO), but is not particularly limited thereto.

The first gate pattern layer GAT1 may include the first gate wiring SBL, the second gate wiring EML, the third gate wiring SWL, a first gate electrode GE1, and a second gate electrode GE2.

Each of the first, second, and third gate wirings SBL, EML, and SWL may extend in the first direction DR1. The first gate wiring SBL may correspond to the j-th black scan line SBLj of FIG. 4A. For example, the j-th black scan signal SBj (refer to FIG. 4A) may be provided to the first gate wiring SBL. The first gate wiring SBL together with the first semiconductor pattern P_ACT1 may constitute the seventh transistor T7 of FIG. 4A.

The second gate wiring EML corresponds to the j-th emission control line EMLj of FIG. 4A. For example, the j-th emission control signal EMj (refer to FIG. 4A) may be provided to the second gate wiring EML. The second gate wiring EML together with the first semiconductor pattern P_ACT1 may constitute the fifth and sixth transistors T5 and T6 of FIG. 4A.

The third gate wiring SWL corresponds to the j-th write scan line SWLj of FIG. 4A. For example, the j-th write scan signal SWj (refer to FIG. 4A) may be provided to the third gate wiring SWL. The third gate wiring SWL together with the first semiconductor pattern P_ACT1 may constitute the second transistor T2 of FIG. 4A, and the third gate wiring SWL together with the second semiconductor pattern S_ACT1 may constitute the output transistor ST3 of FIG. 4A.

Each of the first and second gate electrodes GE1 and GE2 may be an island shaped region. The first gate electrode GE1 together with the first semiconductor pattern P_ACT1 may constitute the first transistor T1 of FIG. 4A. The first gate electrode GE1 may correspond to the third electrode G1 of the first transistor T1 illustrated in FIG. 6. The second gate electrode GE2 together with the second semiconductor pattern S_ACT1 may constitute the amplifying transistor ST2 of FIG. 4A.

Referring to FIG. 9C, the second insulating layer 20 may be on the first insulating layer 10 and may cover the first gate pattern layer GAT1. The second gate pattern layer GAT2 may be on the second insulating layer 20. The second gate pattern layer GAT2 may include metal, an alloy, conductive metal oxide, or a transparent conductive material.

The second gate pattern layer GAT2 may include the fourth-first gate wiring G2_SCL, the fifth-first gate wiring G2_SIL, a sixth-first gate wiring G2_SRL, and a capacitor electrode CSE.

The fourth-first gate wiring G2_SCL, the fifth-first gate wiring G2_SIL, and the sixth-first gate wiring G2_SRL may extend in the first direction DR1. The sixth-first gate wiring G2_SRL corresponds to (or is included in) the reset control line SRL (refer to FIG. 4A). The fourth-first gate wiring G2_SCL may correspond to (or may be included in) the j-th compensation scan line SCLj (refer to FIG. 4A). The fifth-first gate wiring G2_SIL may correspond to (or may be included in) the j-th initialization scan line SILj (refer to FIG. 4A).

The capacitor electrode CSE may overlap the first gate electrode GE1 and may be an island shaped region. For example, the capacitor electrode CSE together with the first gate electrode GE1 may constitute the capacitor Cst (refer to FIG. 4A). The first gate electrode GE1 may correspond to the upper electrode UE illustrated in FIG. 6. An opening CSE_OP penetrating the capacitor electrode CSE may be formed in the capacitor electrode CSE, and the first gate electrode GE1 may be partially exposed through the opening CSE_OP.

Referring to FIG. 9D, the third insulating layer 30 may be on the second insulating layer 20 and may cover the second gate pattern layer GAT2. A second semiconductor pattern layer ACT2 may be on the third insulating layer 30. The second semiconductor pattern layer ACT2 may include an oxide semiconductor. The second semiconductor pattern layer ACT2 may be in a layer different from the first semiconductor pattern layer ACT1 and may not overlap the first semiconductor pattern layer ACT1.

The second semiconductor pattern layer ACT2 includes a third semiconductor pattern P_ACT2 included in the pixel driving circuit P_PD and a fourth semiconductor pattern S_ACT2 included in the sensor driving circuit O_SD.

Referring to FIG. 9E, the fourth insulating layer 40 may be on the third insulating layer 30 and may cover the second semiconductor pattern layer ACT2. The third gate pattern layer GAT3 may be on the fourth insulating layer 40. The third gate pattern layer GAT3 may include metal, an alloy, conductive metal oxide, or a transparent conductive material.

The third gate pattern layer GAT3 may include the fourth-second gate wiring G3_SCL, the fifth-second gate wiring G3_SIL, a sixth-second gate wiring G3_SRL, a second-first horizontal initialization voltage line H_VAIL1, and a second-second horizontal initialization voltage line H_VAIL2. The fourth-second gate wiring G3_SCL, the fifth-second gate wiring G3_SIL, the sixth-second gate wiring G3_SRL, the second-first horizontal initialization voltage line H_VAIL1, and the second-second horizontal initialization voltage line H_VAIL2 extend in the first direction DR1.

The fifth-second gate wiring G3_SIL may overlap the fourth-first gate wiring G2_SCL and the third semiconductor pattern P_ACT2. In some embodiments, the fourth-second gate wiring G3_SCL may make contact with the fourth-first gate wiring G2_SCL through a contact portion. Accordingly, the j-th compensation scan signal SCj applied to the fourth-first gate wiring G2_SCL may be provided to the fourth-second gate wiring G3_SCL. The fourth-first gate wiring G2_SCL, the third semiconductor pattern P_ACT2, and the fourth-second gate wiring G3_SCL may constitute the third transistor T3 of FIG. 4A.

The fifth-second gate wiring G3_SIL may overlap the fifth-first gate wiring G2_SIL and the third semiconductor pattern P_ACT2. The fifth-second gate wiring G3_SIL may be electrically connected with the fifth-first gate wiring G2_SIL. The j-th initialization scan signal SIj may be provided to the fifth-second gate wiring G3_SIL through the fifth-first gate wiring G2_SIL. The fifth-first gate wiring G2_SIL, the third semiconductor pattern P_ACT2, and the fifth-second gate wiring G3_SIL may constitute the fourth transistor T4 of FIG. 4A.

The sixth-second gate wiring G3_SRL may overlap the fourth semiconductor pattern S_ACT2. The sixth-second gate wiring G3_SRL together with the fourth semiconductor pattern S_ACT may constitute the reset transistor ST1 of FIG. 4A2. The sixth-second gate wiring G3_SRL may be electrically connected with the sixth-first gate wiring G2_SRL illustrated in FIG. 9C.

The second-first horizontal initialization voltage line H_VAIL1 and the second-second horizontal initialization voltage line H_VAIL2 may be spaced apart from each other in the second direction DR2. In an embodiment of the present disclosure, the second initialization voltage line VAIL (refer to FIG. 4A) may include a second-first initialization voltage line and a second-second initialization voltage line. The second-first initialization voltage line is connected to at least one pixel (in particular, a first light emitting element of a first pixel) among the plurality of pixels PX illustrated in FIG. 3, and the second-second initialization voltage line is connected to another pixel (e.g., second and third light emitting elements of second and third pixels) among the plurality of pixels PX. In an embodiment of the present disclosure, the first pixel includes the first light emitting element that outputs light of a first color (e.g., red light), the second pixel includes the second light emitting element that outputs light of a second color (e.g., green light), and the third pixel includes the third light emitting element that outputs light of a third color (e.g., blue light).

Here, the second-first horizontal initialization voltage line H_VAIL1 may be a component included in the second-first initialization voltage line, and the second-second horizontal initialization voltage line H_VAIL2 may be a component included in the second-second initialization voltage line. The second-first horizontal initialization voltage line H_VAIL1 applies a second-first horizontal initialization voltage to the first pixel as the second initialization voltage Vaint (refer to FIG. 4A), and the second-second horizontal initialization voltage line H_VAIL2 applies a second-second horizontal initialization voltage to the second and third pixels as the second initialization voltage Vaint. The second-second horizontal initialization voltage may have a voltage level different from that of the second-first horizontal initialization voltage.

The third gate pattern layer GAT3 further includes the first shielding pattern S_SP1. The first shielding pattern S_SP1 may extend from the second-first horizontal initialization voltage line H_VAIL1. However, the present disclosure is not limited thereto. For example, the first shielding pattern S_SP1 may be provided on the second-second horizontal initialization voltage line H_VAIL2, or the first shielding pattern S_SP1 may be provided on each of the second-first horizontal initialization voltage line H_VAIL1 and the second-second horizontal initialization voltage line H_VAIL2.

Referring to FIG. 9F, the fifth insulating layer 50 may be on the fourth insulating layer 40 and may cover at least a portion of the third gate pattern layer GAT3. A first data pattern layer SD1 may be on the fifth insulating layer 50. The first data pattern layer SD1 may include, for example, metal, an alloy, conductive metal oxide, or a transparent conductive material. Hereinafter, for convenience of description and illustration, FIG. 9F shows only some of the components included in the first data pattern layer SD1.

The first data pattern layer SD1 may include a horizontal reset voltage line H_VRL, the bias voltage line VBL, the first horizontal initialization voltage line H_VIL, and a plurality of first connecting electrode patterns C_CNE1.

The horizontal reset voltage line H_VRL, the bias voltage line VBL, and the first horizontal initialization voltage line H_VIL may extend in the first direction DR1. The horizontal reset voltage line H_VRL, the bias voltage line VBL, and the first horizontal initialization voltage line H_VIL may be spaced apart from one another in the second direction DR2.

The horizontal reset voltage line H_VRL may be a component included in the reset voltage line VRL of FIG. 4A. The reset voltage Vrst (refer to FIG. 4A) may be provided to the horizontal reset voltage line H_VRL. The horizontal reset voltage line H_VRL may be electrically connected with the reset transistor ST1. The reset transistor ST1 may receive the reset voltage Vrst through the horizontal reset voltage line H_VRL. The bias voltage line VBL may correspond to the bias voltage line VBL of FIG. 4A. The bias voltage Vbias (refer to FIG. 4A) may be provided to the bias voltage line VBL. The bias voltage line VBL may be connected with the eighth transistor T8 through a contact portion. The eighth transistor T8 may receive the bias voltage Vbias through the bias voltage line VBL.

The first horizontal initialization voltage line H_VIL may be included in the first initialization voltage line VIL of FIG. 4A. The first initialization voltage Vint (refer to FIG. 4A) may be provided to the first horizontal initialization voltage line H_VIL. The first horizontal initialization voltage line H_VIL may be connected with the fourth transistor T4 through a contact portion. The fourth transistor T4 may receive the first initialization voltage Vint through the first horizontal initialization voltage line H_VIL.

The plurality of first connecting electrode patterns C_CNE1 may make contact with one of the first to fourth semiconductor patterns P_ACT1, S_ACT1, P_ACT2, and S_ACT2. The plurality of first connecting electrode patterns C_CNE1 may electrically connect one of the first to fourth semiconductor patterns P_ACT1, S_ACT1, P_ACT2, and S_ACT2 to other wiring or lines. The plurality of first connecting electrode patterns C_CNE1 may be connected with one of the first to fourth semiconductor patterns P_ACT1, S_ACT1, P_ACT2, and S_ACT2 through a contact portion. The plurality of first connecting electrode patterns C_CNE1 may include the first and third connecting electrodes CNE10 and CNE11 illustrated in FIG. 6.

The first data pattern layer SD1 may further include the second shielding pattern S_SP2. In an embodiment of the present disclosure, the second shielding pattern S_SP2 may extend from the first horizontal initialization voltage line H_VIL.

The first data pattern layer SD1 may further include a horizontal data connecting wiring D1_HCL. The horizontal data connecting wiring D1_HCL may extend in the first direction DR1. In an embodiment of the present disclosure, the horizontal data connecting wiring D1_HCL may be a component included in the horizontal data connecting lines H_DCL illustrated in FIG. 5A.

Referring to FIG. 9G, the sixth insulating layer 60 may be on the fifth insulating layer 50 and may cover at least a portion of the first data pattern layer SD1. A second data pattern layer SD2 may be on the sixth insulating layer 60. The second data pattern layer SD2 may include, for example, metal, an alloy, conductive metal oxide, or a transparent conductive material.

The second data pattern layer SD2 includes the first driving voltage line VL1, a shielding electrode wiring RSE, the first line portion RL_P1 of the readout wiring RL (refer to FIG. 6), and a plurality of connecting patterns.

The first driving voltage line VL1 may overlap the pixel driving circuit P_PD. The first driving voltage line VL1 may correspond to the first driving voltage line VL1 of FIG. 4A. The first driving voltage ELVDD (refer to FIG. 4A) may be provided to the first driving voltage line VL1. The first driving voltage line VL1 may be disposed in a mesh shape in the display area DA (refer to FIG. 3) of the display panel DP. The first driving voltage line VL1 may be connected, through a contact portion, with the fifth transistor T5 and the capacitor Cst, which are illustrated in FIG. 4A.

The shielding electrode wiring RSE may be connected with the horizontal reset voltage line H_VRL illustrated in FIG. 9F and may receive the reset voltage Vrst (refer to FIG. 4A) through the horizontal reset voltage line H_VRL. When viewed from above the plane, the shielding electrode wiring RSE may be disposed between the readout wiring RL and the data wiring DL (refer to FIG. 9H). Accordingly, the shielding electrode wiring RSE may perform a shielding function such that a detection signal output from the readout wiring RL does not couple to a data signal.

The first line portion RL_P1 and the vertical reset voltage line V_VRL extend in the second direction DR2 and are spaced apart from each other in the first direction DR1. The readout wiring RL may correspond to the readout lines RL1 to RLh illustrated in FIG. 3. The readout wiring RL may be connected to the sensor driving circuit O_SD illustrated in FIG. 4A (in particular, the output transistor ST3).

The plurality of connecting patterns may include the second initialization connecting pattern C_VAIL and the first initialization connecting pattern C_VIL (refer to FIG. 8A).

The second data pattern layer SD2 may further include a plurality of second connecting electrode patterns C_CNE2. The plurality of second connecting electrode patterns C_CNE2 may include the second and fourth connecting electrodes CNE20 and CNE21 illustrated in FIG. 6.

Referring to FIG. 9H, the seventh insulating layer 70 may be on the sixth insulating layer 60 and may cover at least a portion of the second data pattern layer SD2. A third data pattern layer SD3 may be disposed on the seventh insulating layer 70. The third data pattern layer SD3 may include, for example, metal, an alloy, conductive metal oxide, or a transparent conductive material.

The third data pattern layer SD3 may include the data wiring DL, a vertical data connecting wiring D3_DCL, a second-first vertical initialization voltage line V_VAIL1, the vertical connecting line V_RL, vertical reset voltage lines V_VRL1 and V_VRL2, and a plurality of third connecting electrode patterns C_CNE3.

The data wiring DL, the vertical data connecting wiring D3_DCL, the second-first vertical initialization voltage line V_VAIL1, and the vertical connecting line V_RL may extend in the second direction DR2. The data wiring DL, the vertical data connecting wiring D3_DCL, the second-first vertical initialization voltage line V_VAIL1, and the vertical connecting line V_RL may be spaced apart from one another in the first direction DR1.

The data wiring DL may correspond to the data lines DL1 to DLm illustrated in FIG. 3. The data wiring DL may be connected to the pixel driving circuit P_PD illustrated in FIG. 4A (in particular, the second transistor T2). The vertical data connecting wiring D3_DCL may correspond to the vertical data connecting line V_DCL illustrated in FIG. 5A. The vertical data connecting wiring D3_DCL may be electrically connected with the horizontal data connecting wiring D1_HCL illustrated in FIG. 9F.

The second-first vertical initialization voltage line V_VAIL1 is electrically connected to the second-first horizontal initialization voltage line H_VAIL1 illustrated in FIG. 9E. The third data pattern layer SD3 may further include a second-second vertical initialization voltage line electrically connected to the second-second horizontal initialization voltage line H_VAIL2. The third data pattern layer SD3 may further include the first vertical initialization voltage line V_VIL (refer to FIG. 8A) electrically connected with the first horizontal initialization voltage line H_VIL illustrated in FIG. 9F.

The vertical reset voltage lines V_VRL1 and V_VRL2 may be components included in the reset voltage line VRL of FIG. 4A. The vertical reset voltage lines V_VRL1 and V_VRL2 may be connected with the horizontal reset voltage line H_VRL illustrated in FIG. 9F. The reset voltage line VRL may have a mesh shape by the coupling of the vertical reset voltage lines V_VRL1 and V_VRL2 and the horizontal reset voltage line H_VRL.

The plurality of third connecting electrode patterns C_CNE3 may include the fifth connecting electrode CNE30 and the sixth connecting electrode CNE31 illustrated in FIG. 6.

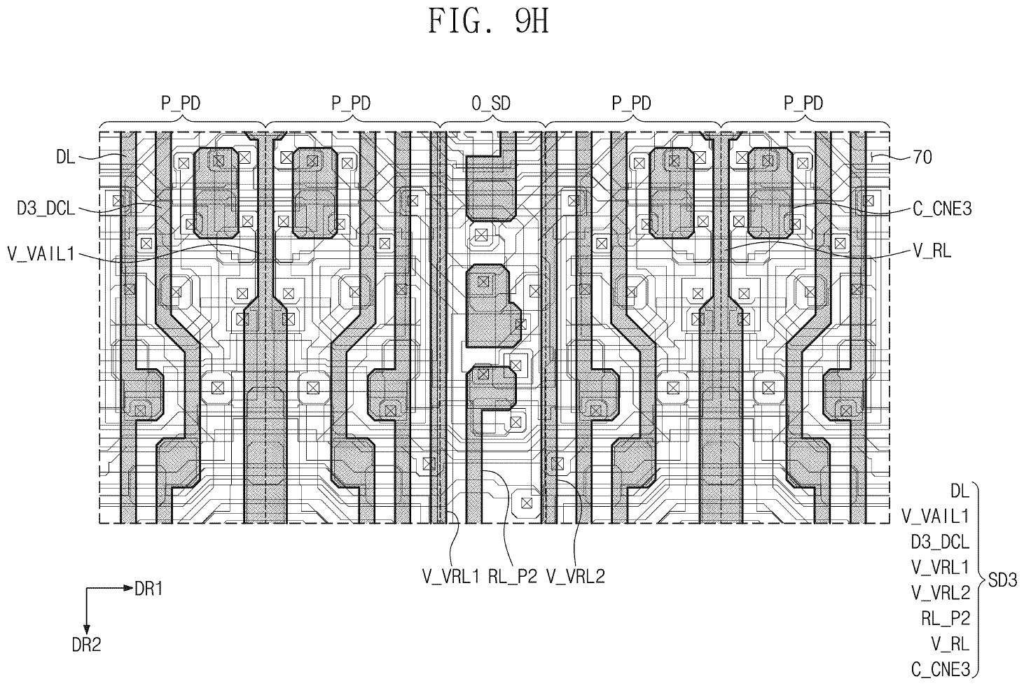

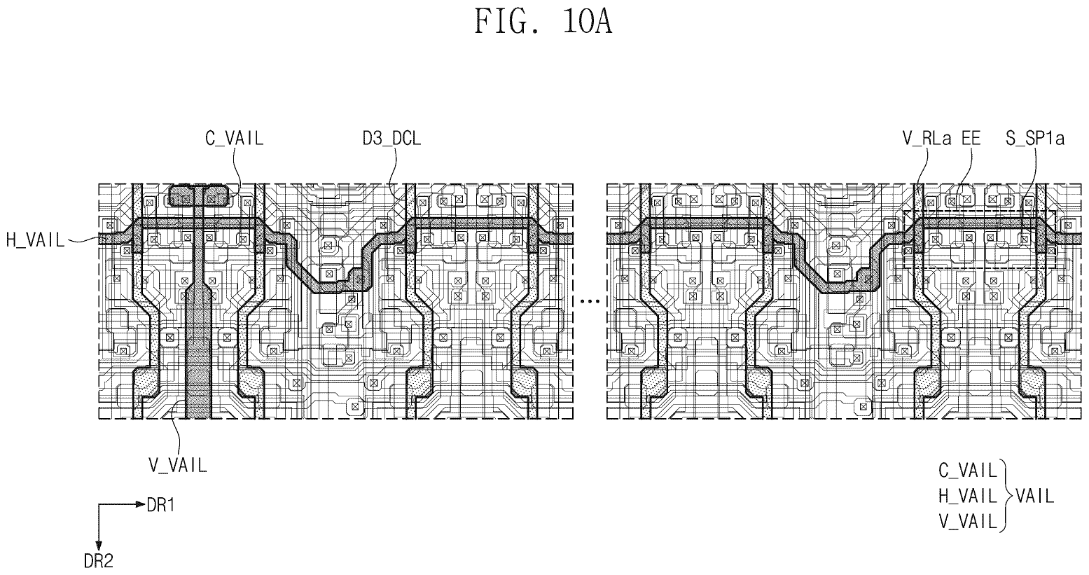

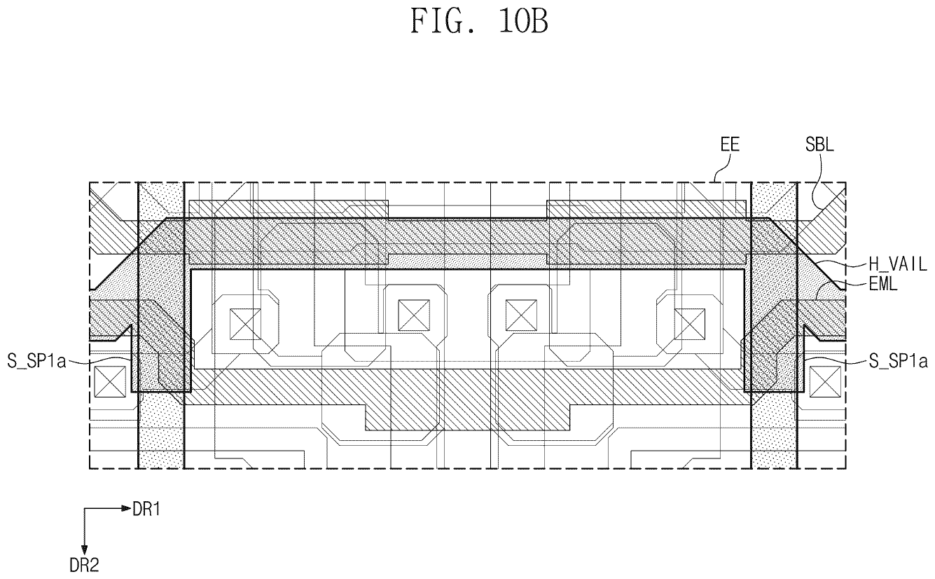

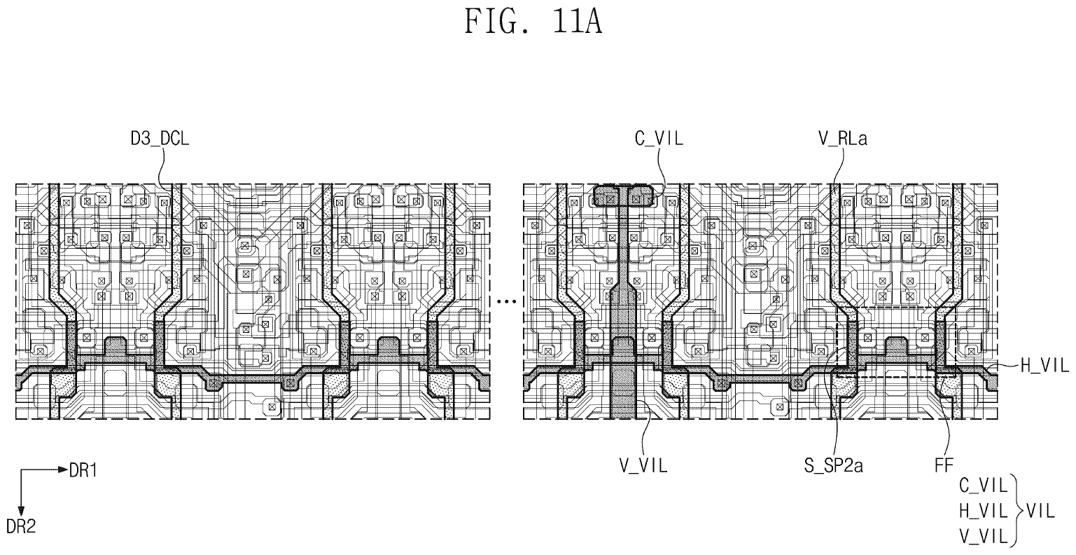

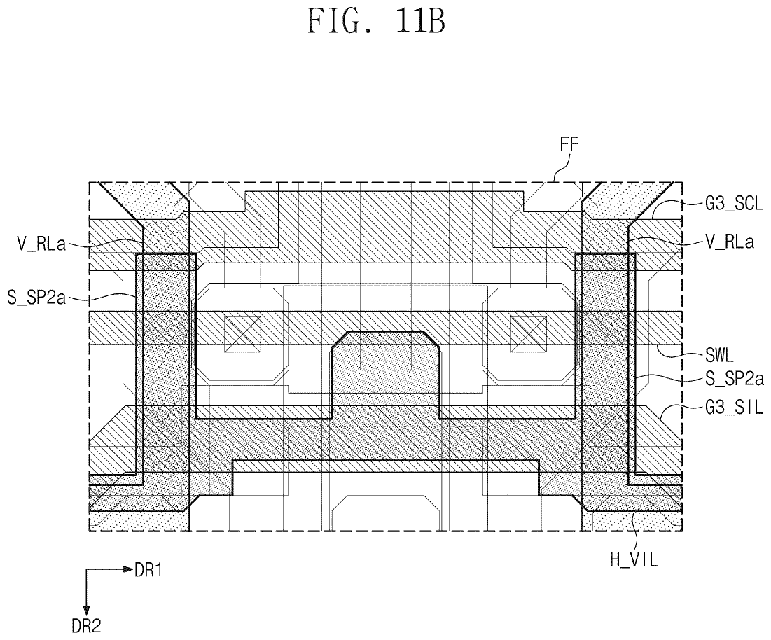

FIG. 10A is a plan view illustrating a portion of a display panel according to an embodiment of the present disclosure, and FIG. 10B is an enlarged view of portion EE of FIG. 10A. FIG. 11A is a plan view illustrating a portion of the display panel according to an embodiment of the present disclosure, and FIG. 11B is an enlarged view of portion FF of FIG. 11A.

Referring to FIGS. 10A and 10B, the second initialization voltage line VAIL includes the second horizontal initialization voltage line H_VAIL and the second vertical initialization voltage line V_VAIL. The second horizontal initialization voltage line H_VAIL extends in the first direction DR1, and the second vertical initialization voltage line V_VAIL extends in the second direction DR2. Accordingly, the second initialization voltage line VAIL may have in a mesh shape in the display area DA of the display panel DP.

Vertical connecting lines V_RLa electrically connected with the second readout lines RL_G2 (refer to FIG. 5A) extend in the second direction DR2. The vertical connecting lines V_RLa may extend parallel to the vertical data connecting wiring D3_DCL.

The vertical connecting lines V_RLa may cross at least one gate wiring. In an embodiment of the present disclosure, each of the vertical connecting lines V_RLa may cross the first gate wiring SBL, the second gate wiring EML, the third gate wiring SWL, and the fourth gate wiring SCL. The first gate wiring SBL may be one of the black scan lines SBL1 to SBLn illustrated in FIG. 3, and the second gate wiring EML may be one of the emission control lines EML1 to EMLn illustrated in FIG. 3. The third gate wiring SWL may be one of the write scan lines SWL1 to SWLn illustrated in FIG. 3, and the fourth gate wiring SCL may be one of the compensation scan lines SCL1 to SCLn illustrated in FIG. 3.

To decrease the third coupling capacitance Ccp3 (refer to FIG. 5B), the display panel DP includes a shielding pattern in the area where each of the vertical connecting lines V_RLa crosses at least one of the first to fourth gate wirings SBL, EML, SWL, and SCL. In an embodiment of the present disclosure, the shielding pattern may include a first shielding pattern S_SP1a extending from the second horizontal initialization voltage line H_VAIL in the second direction DR2. Accordingly, the first shielding pattern S_SP1a may have the same potential (that is, the second initialization voltage Vaint) as the second horizontal initialization voltage line H_VAIL. Since the second initialization voltage Vaint is a DC voltage, the first shielding pattern S_SP1a may have a constant potential.

The first shielding pattern S_SP1a overlaps the vertical connecting lines V_RLa, the first gate wiring SBL, and the second gate wiring EML when viewed from above the plane and is between the vertical connecting lines V_RLa and the first and second gate wirings SBL and EML in the normal direction perpendicular to the plane.

Referring to FIGS. 11A and 11B, the first initialization voltage line VIL includes the first horizontal initialization voltage line H_VIL and the first vertical initialization voltage line V_VIL. The first horizontal initialization voltage line H_VIL extends in the first direction DR1, and the first vertical initialization voltage line V_VIL extends in the second direction DR2.

In an embodiment of the present disclosure, the shielding pattern may further include a second shielding pattern S_SP2a extending from the first horizontal initialization voltage line H_VIL in the direction opposite to the second direction DR2. Accordingly, the second shielding pattern S_SP2a may have the same potential (that is, the first initialization voltage Vint) as the first horizontal initialization voltage line H_VIL. Since the first initialization voltage Vint is a DC voltage, the second shielding pattern S_SP2a may receive the DC voltage.

The second shielding pattern S_SP2a overlaps the vertical connecting lines V_RLa, the third gate wiring SWL, and the fourth gate wiring SCL when viewed from above the plane and is disposed between the vertical connecting lines V_RLa and the third and fourth gate wirings SWL and SCL in the normal direction perpendicular to the plane.

In FIGS. 10B and 11B, the first and second shielding patterns S_SP1a and S_SP2a are illustrated to have a bar shape. However, the present disclosure is not limited thereto, and the first and second shielding patterns S_SP1a and S_SP2a may have a structure extending in various shapes to overlap the gate wirings SBL, EML, SWL, and SCL depending on the design of the pixel PX and the sensor FX.

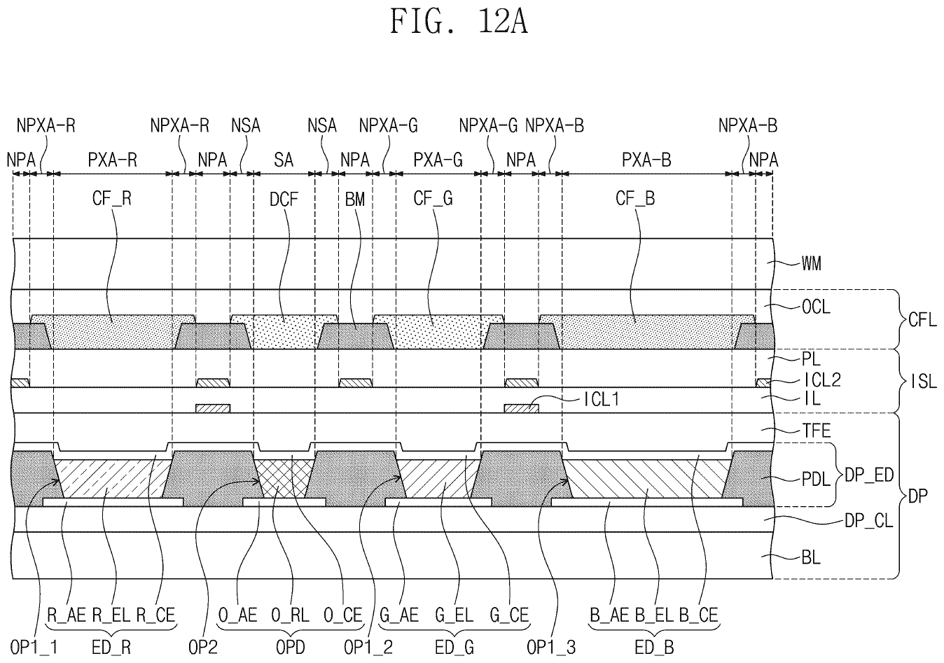

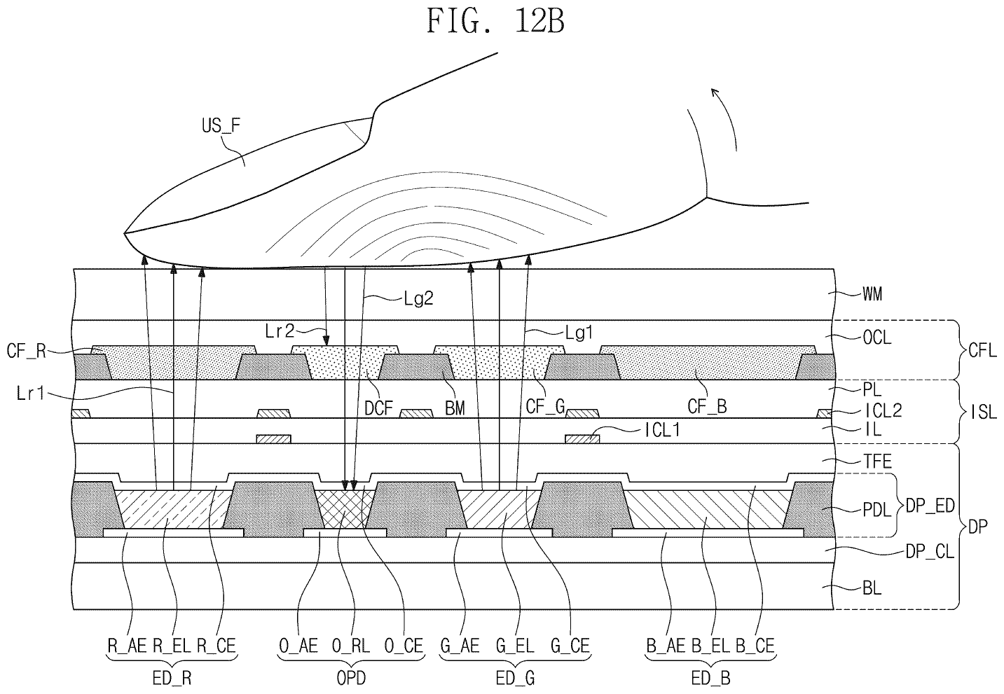

FIGS. 12A and 12B are sectional views illustrating light emitting elements and light receiving elements of a display panel according to an embodiment of the present disclosure.

Referring to FIGS. 12A and 12B, a first electrode layer is on the circuit layer DP_CL. The pixel defining layer PDL is formed on the first electrode layer. The first electrode layer may include red, green, and blue anode electrodes R_AE, G_AE, and B_AE. First to third light emitting openings OP1_1, OP1_2, and OP1_3 of the pixel defining layer PDL expose at least portions of the red, green, and blue anode electrodes R_AE, G_AE, and B_AE, respectively. In an embodiment of the present disclosure, the pixel defining layer PDL may include a black material. The pixel defining layer PDL may, for example, include a black organic dye/pigment, such as carbon black, aniline black, or the like. The pixel defining layer PDL may be formed by mixing a blue organic material and a black organic material. The pixel defining layer PDL may further include a liquid-repellent organic material.

As illustrated in FIG. 12A, the display panel DP may include first to third emissive areas PXA-R, PXA-G, and PXA-B and first to third non-emissive areas NPXA-R, NPXA-G, and NPXA-B adjacent to the first to third emissive areas PXA-R, PXA-G, and PXA-B. The non-emissive areas NPXA-R, NPXA-G, and NPXA-B may surround the corresponding emissive areas PXA-R, PXA-G, and PXA-B, respectively. In this embodiment, the first emissive area PXA-R is defined to correspond to a portion of the red anode electrode R_AE exposed by the first light emitting opening OP1_1. The second emissive area PXA-G is defined to correspond to a portion of the green anode electrode G_AE exposed by the second light emitting opening OP1_2. The third emissive area PXA-B is defined to correspond to a portion of the blue anode electrode B_AE exposed by the third light emitting opening OP1_3. A non-pixel area NPA may be defined between the first to third non-emissive areas NPXA-R, NPXA-G, and NPXA-B.

An emissive layer may be disposed on the first electrode layer. The emissive layer may include red, green, and blue light emitting layers R_EL, G_EL, and B_EL. The red, green, and blue light emitting layers R_EL, G_EL, and B_EL may be in areas respectively corresponding to the first to third light emitting openings OP1_1, OP1_2, and OP1_3. The red, green, and blue light emitting layers R_EL, G_EL, and B_EL may be formed to be separated from one another. Each of the red, green, and blue light emitting layers R_EL, G_EL, and B_EL may include an organic material and/or an inorganic material. The red, green, and blue light emitting layers R_EL, G_EL, and B_EL may generate light of certain colors. For example, the red light emitting layer R_EL may generate red light, the green light emitting layer G_EL may generate green light, and the blue light emitting layer B_EL may generate blue light.

Although the patterned red, green, and blue light emitting layers R_EL, G_EL, and B_EL are illustrated in this embodiment, one light emitting layer may be commonly disposed in the first to third emissive areas PXA_R, PXA_G, and PXA_B. In this case, the light emitting layer may generate white light or blue light. In addition, the light emitting layer may have a multi-layer structure, e.g., a tandem structure.

Each of the red, green, and blue light emitting layers R_EL, G_EL, and B_EL may include a low molecular weight organic material or a high molecular weight organic material as a luminescent material. Alternatively, each of the red, green, and blue light emitting layers R_EL, G_EL, and B_EL may include a quantum-dot material as a luminescent material. A core of a quantum dot may be selected from Group II-VI compounds, Group III-V compounds, Group IV-VI compounds, Group IV elements, Group IV compounds, and combinations thereof.

A second electrode layer is on the red, green, and blue light emitting layers R_EL, G_EL, and B_EL. The second electrode layer may include red, green, and blue cathode electrodes R_CE, G_CE, and B_CE. The red, green, and blue cathode electrodes R_CE, G_CE, and B_CE may be electrically connected with one another. In an embodiment of the present disclosure, the red, green, and blue cathode electrodes R_CE, G_CE, and B_CE may have a one-body shape. In this case, the red, green, and blue cathode electrodes R_CE, G_CE, and B_CE may be commonly disposed in the first to third emissive areas PXA-R, PXA-G, and PXA-B, the first to third non-emissive areas NPXA-R, NPXA-G, and NPXA-B, and the non-pixel area NPA.

The element layer DP_ED may further include a light receiving element OPD. The light receiving element OPD may be a photo diode. The pixel defining layer PDL may further include a light receiving opening OP2 corresponding to the light receiving element OPD.

The light receiving element OPD may include a sensing anode electrode O_AE, a photoelectric conversion layer O_RL, and a sensing cathode electrode O_CE. The sensing anode electrode O_AE may be part of the first electrode layer. That is, the sensing anode electrode O_AE may be on the circuit layer DP_CL and may be simultaneously formed with the red, green, and blue anode electrodes R_AE, G_AE, and B_AE through the same process.

The light receiving opening OP2 of the pixel defining layer PDL exposes at least a portion of the sensing anode electrode O_AE. The photoelectric conversion layer O_RL is on the sensing anode electrode O_AE exposed by the light receiving opening OP2. The photoelectric conversion layer O_RL may include an organic photo sensing material. The sensing cathode electrode O_CE may be on the photoelectric conversion layer O_RL. The sensing cathode electrode O_CE may be simultaneously formed with the red, green, and blue cathode electrodes R_CE, G_CE, and B_CE through the same process. In an embodiment of the present disclosure, the sensing cathode electrode O_CE may have a one-body shape with the red, green, and blue cathode electrodes R_CE, G_CE, and B_CE to form the common cathode electrode C_CE (refer to FIG. 6).

The encapsulation layer TFE is on the element layer DP_ED. The encapsulation layer TFE includes at least an inorganic layer or an organic layer. In an embodiment of the present disclosure, the encapsulation layer TFE may include two inorganic layers and an organic layer therebetween. In an embodiment of the present disclosure, the encapsulation layer TFE may include a plurality of inorganic layers and a plurality of organic layers alternately stacked one above another.

The inorganic layers protect the red, green, and blue light emitting elements ED_R, ED_G, and ED_B and the light receiving element OPD from moisture/oxygen, and the organic layers protect the red, green, and blue light emitting elements ED_R, ED_G, and ED_B and the light receiving element OPD from foreign matter such as dust particles. The inorganic layers may include a silicon nitride layer, a silicon oxynitride layer, a silicon oxide layer, a titanium oxide layer, or an aluminum oxide layer but are not particularly limited thereto. The organic layers may include an acrylic organic layer but are not particularly limited.

The display device DD includes the input sensing layer ISL on the display panel DP and the color filter layer CFL on the input sensing layer ISL.

The input sensing layer ISL may be directly on the encapsulation layer TFE. The input sensing layer ISL includes a first conductive layer ICL1, an insulating layer IL, a second conductive layer ICL2, and a protective layer PL. The first conductive layer ICL1 may be on the encapsulation layer TFE. Although FIGS. 12A and 12B illustrate the structure in which the first conductive layer ICL1 is directly on the encapsulation layer TFE, the present disclosure is not limited thereto. The input sensing layer ISL may further include a base insulating layer between the first conductive layer ICL1 and the encapsulation layer TFE. In this case, the encapsulation layer TFE may be covered by the base insulating layer, and the first conductive layer ICL1 may be on the base insulating layer. In an embodiment of the present disclosure, the base insulating layer may include an inorganic insulating material.

The insulating layer IL may cover the first conductive layer ICL1. The second conductive layer ICL2 is on the insulating layer IL. Although FIGS. 12A and 12B illustrate a structure in which the input sensing layer ISL includes the first and second conductive layers ICL1 and ICL2, the present disclosure is not limited thereto. For example, the input sensing layer ISL may include only one of the first and second conductive layers ICL1 and ICL2.

The protective layer PL may be on the second conductive layer ICL2. The protective layer PL may include an organic insulating material. The protective layer PL may serve to protect the first and second conductive layers ICL1 and ICL2 from moisture/oxygen and may serve to protect the first and second conductive layers ICL1 and ICL2 from foreign matter.

The color filter layer CFL may be on the input sensing layer ISL. The color filter layer CFL may be directly on the protective layer PL. The color filter layer CFL may include a first color filter CF_R, a second color filter CF_G, and a third color filter CF_B. The first color filter CF_R has the first color, the second color filter CF_G has the second color, and the third color filter CF_B has the third color. In an embodiment of the present disclosure, the first color may be red, the second color may be green, and the third color may be blue.

The color filter layer CFL may further include a dummy color filter DCF. In an embodiment of the present disclosure, when the area where the photoelectric conversion layer O_RL is disposed is defined as a sensing area SA and the area around the sensing area SA is defined as a non-sensing area NSA, the area of the dummy color filter DCF may correspond to the sensing area SA. The dummy color filter DCF may overlap the sensing area SA and the non-sensing area NSA. In an embodiment of the present disclosure, the dummy color filter DCF may have the same color as one of the first to third color filters CF_R, CF_G, and CF_B. In an embodiment of the present disclosure, the dummy color filter DCF may have the same green color as the second color filter CF_G.

The color filter layer CFL may further include a black matrix BM. The black matrix BM may overlap the non-pixel area NPA. The black matrix BM may overlap the first and second conductive layers ICL1 and ICL2 in the non-pixel area NPA. In an embodiment of the present disclosure, the black matrix BM may overlap the non-pixel area NPA and the first to third non-emissive areas NPXA-R, NPXA-B, and NPXA-B. The black matrix BM may not overlap the first to third emissive areas PXA-R, PXA-G, and PXA-B.

The color filter layer CFL may further include an overcoating layer OCL. The overcoating layer OCL may include an organic insulating material. The overcoating layer OCL may have a thickness sufficient to remove steps between the first to third color filters CF_R, CF_G, and CF_B. Without any specific limitation, the overcoating layer OCL may include any material that has a certain thickness and is capable of flattening the upper surface of the color filter layer CFL. For example, the overcoating layer OCL may include an acrylic organic material.

Referring to FIG. 12B, when the display device DD (refer to FIG. 1) operates, the red, green, and blue light emitting elements ED_R, ED_G, and ED_B may output light. The red light emitting elements ED_R output red light in a red wavelength band, the green light emitting elements ED_G output green light in a green wavelength band, and the blue light emitting elements ED_B output blue light in a blue wavelength band.

In an embodiment of the present disclosure, the light receiving element OPD may receive light from specific light emitting elements (e.g., the green light emitting elements ED_G) among the red, green, and blue light emitting elements ED_R, ED_G, and ED_B. That is, second light Lg1 may be output from the green light emitting elements ED_G, and the light receiving element OPD may receive second reflected light Lg2 obtained by reflection of the second light Lg1 from the user's fingerprint. The second light Lg1 and the second reflected light Lg2 may be green light in the green wavelength band. The dummy color filter DCF is disposed over the light receiving element OPD. The dummy color filter DCF may be green in color. Accordingly, the second reflected light Lg2 may pass through the dummy color filter DCF and may be incident to the light receiving element OPD.

The red light output from the red light emitting elements ED_R and the blue light output from the blue light emitting elements ED_B may also be reflected by the user's hand US_F. For example, when light obtained by reflection of red light Lr1 output from the red light emitting elements ED_R by the user's hand US_F is defined as first reflected light Lr2, the first reflected light Lr2 may fail to pass through the dummy color filter DCF and may be absorbed by the dummy color filer DCF. Accordingly, the first reflected light Lr2 is not able to pass through the dummy color filter DCF and is not incident on the light receiving element OPD. Likewise, even though blue light is reflected by the user's hand US_F, the blue light may be absorbed by the dummy color filter DCF. Thus, only the second reflected light Lg2 may be provided to the light receiving element OPD.

As described above, the readout lines may be divided into the first and second readout lines, and the second readout lines may be connected with the sensor IC through the connecting lines. Portions of the connecting lines may be disposed in the display area, and thus the area of the region occupied by the connecting lines in the non-display area may be decreased. Accordingly, the area of dead space of the display panel may be decreased.

In addition, a shielding pattern having a constant potential may be disposed between the connecting lines and the gate wirings, and the shielding pattern may decrease the coupling capacitance formed between the connecting lines and the gate wirings. Thus, a deviation in coupling capacitance between the first and second readout lines may be decreased. Accordingly, deterioration in the sensing accuracy of the sensor due to a deviation in coupling capacitance may be prevented.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device having a display area and a non-display area, the display device comprising:
a base layer;
a circuit layer on the base layer; and
an element layer on the circuit layer, the element layer including light emitting elements and light receiving elements in the display area,
wherein the circuit layer includes:
pixel driving circuits connected to the light emitting elements;
sensor driving circuits connected to the light receiving elements;
data lines connected to the pixel driving circuits;
gate wirings connected to the pixel driving circuits;
first readout lines connected to a first group of sensor driving circuits among the sensor driving circuits;
second readout lines spaced apart from the first readout lines in a first direction and connected to a second group of sensor driving circuits among the sensor driving circuits;
connecting lines electrically connected with the second readout lines, respectively, in the display area; and
a shielding pattern configured to overlap the gate wirings and the connecting lines when viewed from above a plane and disposed between the gate wirings and the connecting lines in a normal direction perpendicular to the plane.

2. The display device of claim 1, wherein the connecting lines include:
a plurality of vertical connecting lines extending along the first readout lines; and
a plurality of horizontal connecting lines extending in the first direction and electrically connect the plurality of vertical connecting lines to the second readout lines, and
wherein the shielding pattern overlaps the plurality of vertical connecting lines when viewed from above the plane.

3. The display device of claim 2, wherein the shielding pattern is over the gate wirings and under the plurality of vertical connecting lines.

4. The display device of claim 3, wherein the horizontal connecting lines are disposed on a layer different from a layer on which the vertical connecting lines are disposed, and
wherein the shielding pattern is disposed on a layer different from the layer on which the vertical connecting lines are disposed.

5. The display device of claim 2, wherein the circuit layer further includes a plurality of voltage lines connected to the pixel driving circuits, and
wherein the shielding pattern is connected to at least one of the voltage lines and has a constant potential.

6. The display device of claim 5, wherein the plurality of voltage lines include:
a first initialization voltage line configured to apply a first initialization voltage to the pixel driving circuits; and
a second initialization voltage line configured to apply a second initialization voltage to the pixel driving circuits, and
wherein the shielding pattern includes a first shielding pattern electrically connected to the second initialization voltage line.

7. The display device of claim 6, wherein the second initialization voltage line includes:
a second horizontal initialization voltage line configured to extend in the first direction; and
a second vertical initialization voltage line configured to extend in a second direction crossing the first direction and disposed on a layer different from a layer on which the second horizontal initialization voltage line is disposed.

8. The display device of claim 7, wherein the vertical connecting lines are on the same layer as the second vertical initialization voltage line, and
wherein the first shielding pattern extends from the second horizontal initialization voltage line.

9. The display device of claim 8, wherein the gate wirings include:
a first gate wiring configured to supply a black scan signal to a corresponding pixel driving circuit;
a second gate wiring configured to supply an emission control signal to the corresponding pixel driving circuit;
a third gate wiring configured to supply a write scan signal to the corresponding pixel driving circuit; and
a fourth gate wiring configured to supply a compensation scan signal to the corresponding pixel driving circuit, and
wherein the first shielding pattern overlaps the first and second gate wirings when viewed from above the plane.

10. The display device of claim 6, wherein the shielding pattern further includes a second shielding pattern connected to the first initialization voltage line.

11. The display device of claim 10, wherein the first initialization voltage line includes:
a first horizontal initialization voltage line configured to extend in the first direction; and
a first vertical initialization voltage line configured to extend in a second direction crossing the first direction and disposed on a layer different from a layer on which the first horizontal initialization voltage line is disposed.

12. The display device of claim 11, wherein the vertical connecting lines are on the same layer as the first vertical initialization voltage line, and
wherein the second shielding pattern extends from the first horizontal initialization voltage line.

13. The display device of claim 12, wherein the gate wirings include:
a first gate wiring configured to supply a black scan signal to a corresponding pixel driving circuit;
a second gate wiring configured to supply an emission control signal to the corresponding pixel driving circuit;
a third gate wiring configured to supply a write scan signal to the corresponding pixel driving circuit; and
a fourth gate wiring configured to supply a compensation scan signal to the corresponding pixel driving circuit, and
wherein the second shielding pattern overlaps the third and fourth gate wirings when viewed from above the plane.

14. The display device of claim 1, wherein the data lines include:
first data lines connected to a first group of pixel driving circuits among the pixel driving circuits; and
second data lines spaced apart from the first data lines in the first direction and connected to a second group of pixel driving circuits among the pixel driving circuits, and
wherein the circuit layer further includes data connecting lines electrically connected with the second data lines, respectively, in the display area.

15. The display device of claim 1, further comprising:
a driver chip electrically connected to the circuit layer; and
a sensor chip electrically connected to the circuit layer,
wherein the second readout lines are connected to the sensor chip through the connecting lines.

16. The display device of claim 15, wherein the driver chip and the sensor chip are adjacent to one side of the display area.

17. An electronic device having a display area and a non-display area, the electronic device comprising:
a base layer;
a circuit layer on the base layer; and
an element layer on the circuit layer, the element layer including light emitting elements and light receiving elements in the display area,
wherein the circuit layer includes:
pixel driving circuits connected to the light emitting elements;
sensor driving circuits connected to the light receiving elements;
data lines connected to the pixel driving circuits;
gate wirings connected to the pixel driving circuits;
voltage lines connected to the pixel driving circuits;
first readout lines connected to a first group of sensor driving circuits among the sensor driving circuits;
second readout lines spaced apart from the first readout lines in a first direction and connected to a second group of sensor driving circuits among the sensor driving circuits;
vertical connecting lines electrically connected with the second readout lines, respectively, in the display area and configured to cross the gate wirings; and
a shielding pattern configured to overlap the gate wirings and the vertical connecting lines when viewed from above a plane and disposed between the gate wirings and the vertical connecting lines in a normal direction perpendicular to the plane, wherein the shielding pattern extends from at least one of the voltage lines.

18. The electronic device of claim 17, wherein the voltage lines include:
a first initialization voltage line configured to apply a first initialization voltage to the pixel driving circuits; and
a second initialization voltage line configured to apply a second initialization voltage to the pixel driving circuits, and
wherein the shielding pattern includes a first shielding pattern electrically connected to the second initialization voltage line.

19. The electronic device of claim 18, wherein the second initialization voltage line includes:
a second horizontal initialization voltage line extending in the first direction; and
a second vertical initialization voltage line extending in a second direction crossing the first direction and disposed on a layer different from a layer on which the second horizontal initialization voltage line is disposed.

20. The electronic device of claim 19, wherein the vertical connecting lines are on the same layer as the second vertical initialization voltage line, and
wherein the first shielding pattern extends from the second horizontal initialization voltage line.

21. The electronic device of claim 20, wherein the gate wirings include:
a first gate wiring configured to supply a black scan signal to a corresponding pixel driving circuit;
a second gate wiring configured to supply an emission control signal to the corresponding pixel driving circuit;
a third gate wiring configured to supply a write scan signal to the corresponding pixel driving circuit; and
a fourth gate wiring configured to supply a compensation scan signal to the corresponding pixel driving circuit, and
wherein the first shielding pattern overlaps the first and second gate wirings when viewed from above the plane.

22. The electronic device of claim 18, wherein the shielding pattern further includes a second shielding pattern connected to the first initialization voltage line.

23. The electronic device of claim 22, wherein the first initialization voltage line includes:
a first horizontal initialization voltage line extending in the first direction; and
a first vertical initialization voltage line extending in a second direction crossing the first direction and disposed on a layer different from a layer on which the first horizontal initialization voltage line is disposed.

24. The electronic device of claim 23, wherein the vertical connecting lines are on the same layer as the first vertical initialization voltage line, and
wherein the second shielding pattern extends from the first horizontal initialization voltage line.

25. The electronic device of claim 24, wherein the gate wirings include:
a first gate wiring configured to supply a black scan signal to a corresponding pixel driving circuit;
a second gate wiring configured to supply an emission control signal to the corresponding pixel driving circuit;
a third gate wiring configured to supply a write scan signal to the corresponding pixel driving circuit; and
a fourth gate wiring configured to supply a compensation scan signal to the corresponding pixel driving circuit, and
wherein the second shielding pattern overlaps the third and fourth gate wirings when viewed from above the plane.

26. The electronic device of claim 17, further comprising:
a driver chip electrically connected to the circuit layer; and
a sensor chip electrically connected to the circuit layer,
wherein the second readout lines are connected to the sensor chip through the vertical connecting lines.

27. The electronic device of claim 26, wherein the driver chip and the sensor chip are disposed adjacent to one side of the display area.
